(19) United States
(12) Patent Application Publication
(10) Pub. No.: US 2024/0065077 A1
(43) Pub. Date: Feb. 22, 2024

(54) Display Device, Method For Manufacturing Display Device, and Electronic Device

(71) Applicant: Semiconductor Energy Laboratory Co., LTD., Kanagawa-ken (JP)

(72) Inventors: Daiki Nakamura, Atsugi, Kanagawa (JP); Tomoya AOYAMA, Atsugi, Kanagawa (JP)

(73) Assignee: Semiconductor Energy Laboratory Co., LTD., Kanagawa-ken (JP)

(21) Appl. No.: 18/265,090

(22) PCT Filed: Nov. 24, 2021
(86) PCT No.: PCT/IB2021/060903

§ 371 Date: Jun. 2, 2023

(30) Foreign Application Priority Data
Dec. 7, 2020 (JP) 2020-202400

(51) Int. Cl. H10K 59/80; H10K 59/12

(52) U.S. Cl. CPC H10K 59/879; H10K 59/1201

(57) ABSTRACT

A display device that can display a high-quality image is provided. The display device includes a first conductive layer, a second conductive layer, a light-emitting layer, and a lens. The light-emitting layer is provided over the first conductive layer, the second conductive layer is provided over the light-emitting layer, and the lens is provided over the second conductive layer. The lens contains a photosensitive material. An end portion of the lens is located more outward than an end portion of the light-emitting layer and an end portion of the second conductive layer. The display device further includes an insulating layer, and the insulating layer includes a region in contact with a top surface of the lens, a region in contact with a side surface of the second conductive layer, and a region in contact with a side surface of the light-emitting layer.

### TECHNICAL FIELD

One embodiment of the present invention relates to a display device. One embodiment of the present invention relates to a method for manufacturing a display device. One embodiment of the present invention relates to an electronic device.

Note that one embodiment of the present invention is not limited to the above technical field. Examples of the technical field of one embodiment of the present invention disclosed in this specification and the like include a semiconductor device, a display device, a light-emitting device/apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher-resolution display panels have been required. As a device that requires a high-resolution display panel, a device for virtual reality (VR) or augmented reality (AR) has been actively developed in recent years.

Examples of a display device that can be used for a display panel include, typically, a light-emitting device including a light-emitting element such as an organic EL (Electro Luminescence) element or a light-emitting diode (LED).

For example, the basic structure of an organic EL element is a structure in which a layer containing a light-emitting organic compound is provided between a pair of electrodes. By applying a voltage to this element, light emission can be obtained from the light-emitting organic compound. A display device using such an organic EL element does not need a backlight that is necessary for a liquid crystal display device and the like; thus, a thin, lightweight, high-contrast, and low-power display device can be achieved. Patent Document 1, for example, discloses an example of a display device using an organic EL element.

### REFERENCE

### Patent Document

[Patent Document 1] Japanese Published Patent Application No. 2002-324673

### SUMMARY OF THE INVENTION

### Problems to be Solved by the Invention

When the pixel density is increased in accordance with the miniaturization of pixels, so-called crosstalk in which light emitted by a light-emitting element enters a coloring layer provided in adjacent pixels is generated in some cases. Thus, the quality of an image displayed on a display device is decreased in some cases.

An object of one embodiment of the present invention is to provide a display device that can display a high-quality image. Another object of one embodiment of the present invention is to provide a high-definition display device. Another object of one embodiment of the present invention is to provide a display device that can be manufactured by a simple method. Another object of one embodiment of the present invention is to provide a low-cost display device. Another object of one embodiment of the present invention is to provide a highly reliable display device. Another object of one embodiment of the present invention is to provide a novel display device.

Another object of one embodiment of the present invention is to provide a method for manufacturing a display device that is capable of displaying high-quality images. Another object of one embodiment of the present invention is to provide a method for manufacturing a high-definition display device. Another object of one embodiment of the present invention is to provide a simple method for manufacturing a display device. Another object of one embodiment of the present invention is to provide a method for manufacturing a low-cost display device. Another object of one embodiment of the present invention is to provide a method for manufacturing a highly reliable display device. Another object of one embodiment of the present invention is to provide a novel method for manufacturing a display device.

Note that the description of these objects does not preclude the existence of other objects. One embodiment of the present invention does not need to achieve all these objects. Note that other objects can be derived from the description of the specification, the drawings, the claims, and the like.

### Means for Solving the Problems

One embodiment of the present invention is a display device including a first conductive layer, a second conductive layer, a light-emitting layer, and a lens; the light-emitting layer is provided over the first conductive layer; the second conductive layer is provided over the light-emitting layer; the lens is provided over the second conductive layer; the lens contains a photosensitive material; an end portion of the lens is located more outward than an end portion of the light-emitting layer and an end portion of the second conductive layer.

Alternatively, in the above embodiment, the lens may contain an acrylic resin.

Alternatively, in the above embodiment, a first insulating layer may be included; the first insulating layer may include a region in contact with a top surface of the lens, a region in contact with a side surface of the second conductive layer, and a region in contact with a side surface of the light-emitting layer.

Alternatively, in the above embodiment, a second insulating layer may be included; the second insulating layer may be provided between the second conductive layer and the lens; and an end portion of the second insulating layer may be located more inward than the end portion of the lens.

Another embodiment of the present invention may include a first conductive layer, a second conductive layer, a third conductive layer, a fourth conductive layer, a first light-emitting layer, a second light-emitting layer, a first lens, a second lens, a first coloring layer, and a second coloring layer; the first light-emitting layer is provided over the first conductive layer; the second conductive layer is provided over the first light-emitting layer; the first lens is provided over the second conductive layer; the first coloring layer is provided over the first lens; the second light-emitting layer is provided over the third conductive layer; the fourth conductive layer is provided over the second light-emitting layer; the second lens is provided over the fourth conductive layer; the second coloring layer is provided over the second lens; the first lens and the second lens each contain a photosensitive material; an end portion of the first lens is located more outward than an end portion of the first light-emitting layer and an end portion of the second conductive layer; an end portion of the second lens is located more outward than an end portion of the second light-emitting layer and an end portion of the fourth conductive layer; the first light-emitting layer and the second light-emitting layer have a function of emitting light with the same color as each other; and the first coloring layer and the second coloring layer have a function of transmitting light with different colors from each other.

Alternatively, in the above embodiment, the first lens and the second lens may include an acrylic resin.

Alternatively, in the above embodiment, a first insulating layer may be included; the first insulating layer may include a region in contact with a top surface of the first lens, a region in contact with a top surface of the second lens, a region in contact with a side surface of the second conductive layer, a region in contact with a side surface of the fourth conductive layer, a region in contact with the first light-emitting layer, and a region in contact with a side surface of the second light-emitting layer.

Alternatively, in the above embodiment, a second insulating layer and a third insulating layer may be included; the second insulating layer may be provided between the second conductive layer and the first lens; the third insulating layer may be provided between the fourth conductive layer and the second lens; an end portion of the second insulating layer may be located more inward than the end portion of the first lens; and an end portion of the third insulating layer may be located more inward than the end portion of the second lens.

Another embodiment of the present invention is an electronic device including the display device of one embodiment of the present invention and an operation button.

Another embodiment of the present invention is a method for manufacturing a display device including steps of forming a first conductive layer over a substrate, depositing a film that is to be a light-emitting layer over the first conductive layer, depositing a film that is to be a second conductive layer, forming a resist mask over the film that is to be a second conductive layer so as to have a region overlapping with the first conductive layer, etching the film that is to be a second conductive layer and the film that is to be a light-emitting layer with use of the resist mask as a mask, so that the second conductive layer and the light-emitting layer are formed, and heating the substrate to make the resist mask a lens.

Alternatively, in the above embodiment, a first insulating layer may be deposited after the formation of the lens.

Alternatively, in the above embodiment, the first insulating layer may be formed by an ALD method.

Alternatively, in the above embodiment, a film that is to be a second insulating layer may be deposited after the formation of the film that is to be a second conductive layer and before the formation of the resist mask; and the film that is to be a second insulating layer, the film that is to be a second conductive layer, and the film that is to be a light-emitting layer may be etched with use of the resist mask as a mask after the formation of the resist mask, so that the second insulating layer, the second conductive layer, and the light-emitting layer are formed.

### Effect of the Invention

According to one embodiment of the present invention, a display device that can display a high-quality image can be provided. According to another embodiment of the present invention, a high-definition display device can be provided. According to another embodiment of the present invention, a display device that can be manufactured by a simple method can be provided. According to another embodiment of the present invention, a low-cost display device can be provided. According to another embodiment of the present invention, a highly reliable display device can be provided. According to another embodiment of the present invention, a novel display device can be provided.

According to another embodiment of the present invention, a method for manufacturing a display device that is capable of displaying high-quality images can be provided. According to another embodiment of the present invention, a method for manufacturing a high-definition display device can be provided. According to another embodiment of the present invention, a simple method for manufacturing a display device can be provided. According to another embodiment of the present invention, a method for manufacturing a low-cost display device can be provided. According to another embodiment of the present invention, a method for manufacturing a highly reliable display device can be provided. According to another embodiment of the present invention, a novel method for manufacturing a display device can be provided.

Note that the description of these effects does not preclude the existence of other effects. One embodiment of the present invention does not need to have all these effects. Other effects can be derived from the description of the specification, the drawings, the claims, and the like.

### BRIEF DESCRIPTION OF THE DRAWINGS

FIG. 1 is a cross-sectional view of a structure example of a display device.

FIG. 2A to FIG. 2D are cross-sectional views illustrating an example of a method for manufacturing a display device.

FIG. 3A to FIG. 3D are cross-sectional views illustrating an example of a method for manufacturing a display device.

FIG. 4 is a cross-sectional view illustrating a structure example of a display device.

FIG. 5A and FIG. 5B are block diagrams each illustrating a structure example of a display device.

FIG. 6A and FIG. 6B are perspective views illustrating a structure example of a touch panel.

FIG. 7A1 to FIG. 7C1 and FIG. 7A2 to FIG. 7C2 are cross-sectional views each illustrating a transistor structure example.

FIG. 8A1 to FIG. 8A3, FIG. 8B1, FIG. 8B2, FIG. 8C1, and FIG. 8C2 are cross-sectional views each illustrating a transistor structure example.

FIG. 9A to FIG. 9F are diagrams illustrating a structure example of an electronic device.

FIG. 10A and FIG. 10B are diagrams illustrating a structure example of a display module.

FIG. 11A and FIG. 11B are diagrams illustrating a structure example of an electronic device.

FIG. 12A to FIG. 12E are diagrams illustrating structure examples of electronic devices.

FIG. 13A to FIG. 13G are diagrams illustrating structure examples of electronic devices.

FIG. 14A to FIG. 14D are diagrams illustrating structure examples of electronic devices.

### MODE FOR CARRYING OUT THE INVENTION

Hereinafter, embodiments are described with reference to the drawings. Note that the embodiments can be implemented in many different modes, and it will be readily understood by those skilled in the art that modes and details thereof can be changed in various ways without departing from the spirit and scope thereof. Thus, the present invention should not be construed as being limited to the following description of the embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

In each drawing described in this specification, the size, the layer thickness, or the region of each component is exaggerated for clarity in some cases. Therefore, they are not limited to the illustrated scale.

In this specification and the like, the ordinal numbers such as “first” and “second” are used in order to avoid confusion among components and do not limit the number.

Note that the expressions indicating directions, such as “over” and “under,” are basically used to correspond to the directions in the drawings. However, in some cases, the term “over” or “under” in the specification indicates a direction that does not correspond to the apparent direction in the drawings, for the purpose of easy description or the like. For example, when the stacked order (or formation order) of a stack is described, even in the case where a surface on which the stack is provided (e.g., a formation surface, a support surface, a bonding surface, or a flat surface) is positioned above the stack in the drawings, the direction and the opposite direction are referred to as “under” and “over”, respectively, in some cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS FET or an OS transistor is mentioned, it can also be referred to as a transistor including a metal oxide or an oxide semiconductor.

In this specification and the like, a device formed using a metal mask or an FMM (fine metal mask, high-resolution metal mask) may be referred to as a device having an MM (metal mask) structure. In this specification and the like, a device formed without using a metal mask or an FMM may be referred to as a device having an MML (metal maskless) structure.

### Embodiment 1

Described in this embodiment will be a structure example of a display device of one embodiment of the present invention, an example of a manufacturing method of a display device of one embodiment of the present invention, and the like.

One embodiment of the present invention relates to a display device including a light-emitting element such as an organic EL element as a display element and a manufacturing method thereof. In order to manufacture the display device of one embodiment of the present invention, first, a first conductive layer is formed over a first substrate. Next, a film that is to be a light-emitting layer is deposited over the first conductive layer. Then, a film that is to be a second conductive layer is deposited over the film that is to be a light-emitting layer.

Next, a resist mask is formed over the film that is to be a second conductive layer to have a region overlapping with the first conductive layer. After that, the film that is to be a second conductive layer and the film that is to be a light-emitting layer are etched with use of the resist mask as a mask. Thus, an island-shaped second conductive layer and an island-shaped light-emitting layer are formed. The light-emitting element has a structure where the light-emitting layer is provided between the first conductive layer and the second conductive layer. The first conductive layer serves as one of electrodes of the light-emitting element, and the second conductive layer serves as the other electrode of the light-emitting element.

Next, the first substrate over which the light-emitting element is formed is heated, for example. Thus, the resist mask is changed in shape to be a convex and accordingly has a function of a lens. After that, an insulating layer is formed so as to have a region in contact not only with the resist mask but also with a side surface of the second conductive layer and a side surface of the light-emitting layer.

Next, a coloring layer is formed over a second substrate, and the coloring layer and the insulating layer are bonded to each other with an adhesive layer. The above is an example of a method for manufacturing a display device of one embodiment of the present invention.

In the display device manufactured by the above method, the light-emitting layer can be isolated between pixels, and an electrode provided over the light-emitting layer (the other electrode of the light-emitting element) can be isolated between the pixels. This structure can inhibit the generation of crosstalk due to the oblique electric field emitted by the one of the electrodes of the light-emitting element. Thus, high-quality images can be displayed. In addition, even in the case where the pixels are miniaturized to have the pixel density increased, the generation of crosstalk can be inhibited. Thus, the display device of one embodiment of the present invention can be a high-definition display device.

In the above manufacturing method, after the second conductive layer and the light-emitting layer are formed through the etching using the resist mask as a mask, the resist mask is heated to turn into a lens. Thus, the manufacturing process can be simplified as compared to the case where a lens is formed after the resist mask is removed, for example. In this manner, the display device can be manufactured by a simple method, and the display device of one embodiment of the present invention can be a low-cost display device.

In this specification and the like, the term “element” can be replaced with the term “device” in some cases. For example, a light-emitting element can be referred to as a light-emitting device.

In the case where the expression “B over A” or “B under A” is used in this specification and the like, for example, A and B do not always need to include a region where they are in contact with each other.

### Structure Example 1

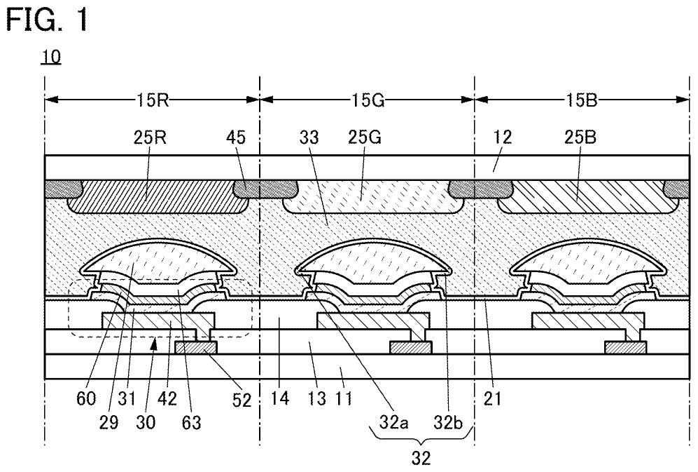

FIG. 1 is a cross-sectional view illustrating a structure example of a display device 10, which is a display device of one embodiment of the present invention. The display device 10 includes a pixel 15R, a pixel 15G, and a pixel 15B. Here, the pixel 15R, the pixel 15G, and the pixel 15B are provided on a display surface of the display device 10. The display surface can have a structure in which the pixels 15R, the pixels 15G, and the pixels 15B are arranged in a matrix. It can be said that one pixel is composed of the pixel 15R, the pixel 15G, and the pixel 15B, and the pixels are arranged in a matrix on the display surface of the display device 10. In this case, the pixel 15R, the pixel 15G, and the pixel 15B can be referred to as sub-pixels.

The display device 10 includes a substrate 11, a transistor 52, an insulating layer 13, a light-emitting element 30, a partition 14, an insulating layer 63, a lens 29, an insulating layer 21, an adhesive layer 33, a coloring layer 25R, a coloring layer 25G, a coloring layer 25B, a light-blocking layer 45, and a substrate 12. Note that the coloring layer 25R, the coloring layer 25G, and the coloring layer 25B are collectively referred to as a coloring layer 25. The pixel 15R, the pixel 15G, and the pixel 15B each include one light-emitting element 30 and one lens 29. The insulating layer 63 is provided and isolated for each pixel. The coloring layer 25R is provided in the pixel 15R, the coloring layer 25G is provided in the pixel 15G, and the coloring layer 25B is provided in the pixel 15B.

In the display device 10 illustrated in FIG. 1, the pixel 15G is adjacent to the pixel 15R and the pixel 15B. Here, the light-emitting elements 30, the coloring layers, or the lenses 29 provided in adjacent pixels can be said to be adjacent to each other. For example, in FIG. 1, the light-emitting element 30 provided in the pixel 15R and the light-emitting element 30 provided in the pixel 15G can be said to be adjacent to each other. In addition, the coloring layer 25R and the coloring layer 25G that are illustrated in FIG. 1 can be said to be adjacent to each other. Furthermore, in FIG. 1, the lens 29 provided in the pixel 15R and the lens 29 provided in the pixel 15G can be said to be adjacent to each other. Although the pixel 15R and the pixel 15B are not adjacent to each other in FIG. 1, the pixel 15R and the pixel 15B may be adjacent to each other.

The insulating layer 13 and the transistor 52 are provided over the substrate 11. The light-emitting element 30 is provided over the insulating layer 13. The insulating layer 63 is provided over the light-emitting element 30. The lens 29 is provided over the insulating layer 63. The insulating layer 21 is provided over the lens 29 and the partition 14. The adhesive layer 33 is provided over the insulating layer 21. The coloring layer 25R, the coloring layer 25G, the coloring layer 25B, and the light-blocking layer 45 are provided over the adhesive layer 33. The substrate 12 is provided over the coloring layer 25R, the coloring layer 25G, the coloring layer 25B, and the light-blocking layer 45.

As the substrate 11, an insulating substrate such as a glass substrate, a quartz substrate, a sapphire substrate, or a ceramic substrate, a single crystal semiconductor substrate or a polycrystalline semiconductor substrate including silicon, silicon carbide, or the like as a material, a compound semiconductor substrate of silicon germanium or the like, or a semiconductor substrate such as an SOI substrate can be used. As the substrate 12, a substrate having a visible light transmitting property is used, for example. As the substrate 12, a glass substrate, a quartz substrate, a sapphire substrate, or the like can be used, for example. Substrates having flexibility are used as the substrate 11 and the substrate 12, whereby the display device 10 can be a flexible display device.

An organic insulating film, for example, is preferably used as the insulating layer 13. Examples of the organic insulating film include an acrylic resin, a polyimide resin, an epoxy resin, a polyamide resin, a polyimide-amide resin, a siloxane resin, a benzocyclobutene-based resin, a phenol resin, and precursors of these resins. As the insulating layer 63 and the insulating layer 21, for example, an inorganic insulating film is preferably used. As the inorganic insulating film, for example, an aluminum oxide film, an aluminum nitride film, a silicon nitride film, a silicon oxynitride film, a silicon oxide film, a silicon nitride oxide film, or the like can be used. A hafnium oxide film, a hafnium oxynitride film, a hafnium nitride oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used. Note that an inorganic insulating film may be used as the insulating layer 13, and an organic insulating film may be used as the insulating layer 63 and the insulating layer 21. As any other insulating layer included in the display device 10, a material similar to the material that can be used as the insulating layer 13, the insulating layer 63, or the insulating layer 21 can be used.

Note that in this specification and the like, silicon oxynitride is a material that contains more oxygen than nitrogen in its composition. Moreover, silicon nitride oxide is a material that contains more nitrogen than oxygen in its composition.

As illustrated in FIG. 1, the coloring layer 25R, the coloring layer 25G, and the coloring layer 25B are provided over their respective light-emitting elements 30 and their respective lens 29. Thus, the light-emitting element 30, the lens 29, and the coloring layer 25R are provided to have a region where they overlap with one another. The light-emitting element 30, the lens 29, and the coloring layer 25G are provided to have a region where they overlap with one another. The light-emitting element 30, the lens 29, and the coloring layer 25B are provided to have a region where they overlap with one another.

The light-emitting element 30 has a structure in which a conductive layer 42, a light-emitting layer 31, and a conductive layer 60 are stacked. Here, the conductive layer 42 can be one of electrodes of the light-emitting element 30 and the conductive layer 60 can be the other electrode of the light-emitting element 30. Specifically, the conductive layer 42 can be used as a pixel electrode of the light-emitting element 30, for example.

The light-emitting element 30 can emit white light, for example. Specifically, white light can be emitted by the light-emitting layer 31. As the light-emitting element 30, an EL element such as an OLED (Organic Light Emitting Diode) or a QLED (Quantum-dot Light Emitting Diode) can be used. As the light-emitting element 30, a micro LED can be used.

In the case where a light-emitting element emitting white light is used as the light-emitting element 30, the light-emitting layer 31 preferably contains two or more kinds of light-emitting substances. White emission can be obtained by selecting two or more light-emitting substances so that the light-emitting substances emit light of complementary colors, for example. For example, the light-emitting layer preferably contains two or more light-emitting substances that emit light of red (R), green (G), blue (B), yellow (Y), orange (0), and the like. Alternatively, the light-emitting layer preferably contains a light-emitting substance that emits light containing two or more spectral components of R, G, and B. A light-emitting element whose emission spectrum has two or more peaks in the wavelength range of a visible light region (e.g., 350 nm to 750 nm) is preferably employed. An emission spectrum of a material emitting light having a peak in a yellow wavelength range preferably includes spectral components also in green and red wavelength ranges.

The light-emitting layer 31 preferably has a structure in which a light-emitting layer containing a light-emitting material emitting light of one color and a light-emitting layer containing a light-emitting material emitting light of another color are stacked. For example, the plurality of light-emitting layers in the light-emitting layer 31 may be stacked in contact with each other or may be stacked with a region not including any light-emitting material therebetween. For example, between a fluorescent light-emitting layer and a phosphorescent light-emitting layer, a region that contains the same material as the fluorescent light-emitting layer or the phosphorescent light-emitting layer (for example, a host material or an assist material) and a region that contains no light-emitting material may be provided. This facilitates the fabrication of the light-emitting element and reduces the drive voltage. When the light-emitting element 30 has a structure in which a plurality of light-emitting layers 31 are stacked, the plurality of light-emitting layers 31 may be stacked with a charge generation layer positioned therebetween.

The conductive layer 42 can be electrically connected to the transistor 52 through an opening that is provided in the insulating layer 13 and reaches the transistor 52. For example, the conductive layer 42 can be electrically connected to a source or a drain of the transistor 52.

For the conductive layer 42, a metal material such as molybdenum, titanium, chromium, tantalum, tungsten, aluminum, copper, neodymium, or scandium or an alloy material which contains any of these materials as its main component can be used. As the conductive layer 42, a stacked film of three layers in which a titanium film, an aluminum film provided over the titanium film, and a titanium film provided over the aluminum film are stacked in that order; or a stacked film of three layers in which a molybdenum film, an aluminum film provided over the molybdenum film, and a molybdenum film provided over the aluminum film are stacked in that order is preferably used. Needless to say, a single-layer film, a stacked film of two layers, or a stacked film of four or more layers may also be used as the metal conductive film.

The partition 14 has a function of electrically insulating (also referred to as electrically isolating) the conductive layers 42 included in the different light-emitting elements 30. An end portion of the conductive layer 42 is covered with the partition 14.

An inorganic insulating film is preferably used as the partition 14. For example, a material similar to the material that can be used for the insulating layer 63 or the like can be used for the partition 14. Note that an organic insulating film may be used for the partition 14. The partition 14 is a layer that transmits visible light. A partition that blocks visible light may be provided instead of the partition 14.

For example, a material that transmits visible light can be used for the conductive layer 60. For example, an indium tin oxide (ITO) film formed by mixing tin oxide into indium oxide, an indium tin silicon oxide (ITSO) film formed by mixing silicon oxide into indium tin oxide (ITO), an indium zinc oxide (IZO (registered trademark)) film formed by mixing zinc oxide into indium oxide, a zinc oxide film, or a tin oxide film can be used. Furthermore, the following materials can be used as a material included in the conductive layer 60: an oxide conductor or a metal oxide, such as an oxide including indium and tin (In—Sn oxide), an oxide including indium and tungsten (In—W oxide), an oxide including indium, tungsten, and zinc (In—W—Zn oxide), an oxide including indium and titanium (In—Ti oxide), an oxide including indium, titanium, and tin (In—Ti—Sn oxide), an oxide including indium and zinc (In—Zn oxide), an oxide including indium, tin, and silicon (In—Sn—Si oxide), or an oxide including indium, gallium, and zinc (In—Ga—Zn oxide).

Here, an oxide conductor is described. When hydrogen is added to a metal oxide in which oxygen vacancies are generated, a donor level is formed in the vicinity of the conduction band. As a result, the conductivity of the metal oxide is increased, so that the metal oxide becomes a conductor. The metal oxide having become a conductor can be referred to as an oxide conductor. Metal oxides generally have a visible light transmitting property because of their large energy gap. Meanwhile, an oxide conductor is a metal oxide having a donor level in the vicinity of the conduction band. Therefore, the influence of absorption due to the donor level is small in an oxide conductor, and an oxide conductor has a visible light transmitting property comparable to that of a metal oxide.

Alternatively, the conductive layer 60 may have a stacked-layer structure of a conductive film having transflective properties and a conductive film having a transmitting property. Specifically, the conductive layer 60 may have a structure in which a conductive film having a transmitting property is provided over a conductive film having transflective properties. With the conductive film having transflective properties included in the conductive layer 60, a so-called microcavity structure is achieved, so that the intensity of light with a specific wavelength, of light emitted by the light-emitting layers 31, can be increased. In this structure, it is preferable to vary an optical path length of light emitted by the light-emitting layer 31 depending on colors of light extracted from pixels. In other words, it is preferable to make an optical path length of light emitted by the light-emitting layer 31 different between the light-emitting layer 31 included in the pixel 15R, the light-emitting layer 31 included in the pixel 15G, and the light-emitting layer 31 included in the pixel 15B. To vary the optical path length of light emitted by the light-emitting layer 31, the conductive layer 42 may have a stacked-layer structure of a visible-light-reflecting material such as a metal material and a visible-light-transmitting material.

For the conductive film having transflective properties, a metal material such as aluminum, gold, platinum, silver, nickel, tungsten, chromium, molybdenum, iron, cobalt, copper, or palladium or an alloy containing any of these metal materials can be used, for example. Lanthanum, neodymium, germanium, or the like may be added to the metal material or the alloy. Alternatively, an alloy (an aluminum alloy) containing aluminum and titanium, nickel, or neodymium may be used. Alternatively, an alloy containing silver and copper, palladium, or magnesium may be used. An alloy containing silver and copper is preferable because of its high heat resistance. Furthermore, when a metal film or a metal oxide film is stacked in contact with an aluminum film or an aluminum alloy film, oxidation can be inhibited. Examples of a material for the metal film or the metal oxide film include titanium and titanium oxide. Alternatively, the above conductive film that transmits visible light and a film containing a metal material may be stacked. For example, a stacked-layer film of silver and indium tin oxide or a stacked-layer film of an alloy of silver and magnesium and indium tin oxide can be used.

As illustrated in FIG. 1, the insulating layer 63 is provided over the conductive layer 60, and the lens 29 is provided over the insulating layer 63. This structure can inhibit a substance contained in the lens 29 from entering the light-emitting layer 31 through the conductive layer 60, for example. That is, the entry of impurities into the light-emitting layer 31 can be inhibited, and accordingly the reliability of the light-emitting element 30 can be increased. According to the above description, the insulating layer 63 functions as a protective layer for the light-emitting element 30. Note that assuming that the conductive layer 60 functions as a protective layer, the insulating layer 63 is not necessarily provided in the display device 10 when the conductive layer 60 has low permeation of impurities.

The lens 29 has a function of condensing light emitted by the light-emitting layer 31 toward the front direction of a display surface of the display device 10. The lens 29 contains a photosensitive material, e.g., an acrylic resin. The lens 29 is formed by changing the shape of the resist mask used as a mask in photolithography, for example: the details will be described later. For example, a material containing an acrylic resin can have both a function as a resist mask and a function of a lens. The lens 29 preferably has high visible-light transmitting properties, in which case light emitted by the light-emitting layer 31 can be extracted efficiently.

The lens 29 can have a structure where the convex portion faces the substrate 12 side. Thus, the convex portion of the lens 29 can be a top surface of the lens 29. The convex portion of the lens 29 can have a spherical surface, for example.

Here, an end portion of the lens 29 is located more outward than an end portion of the light-emitting layer 31, an end portion of the conductive layer 60, and an end portion of the insulating layer 63. The end portion of the lens 29 is represented as an end portion 32 (an end portion 32a and an end portion 32b in FIG. 1 or the like).

The insulating layer 21 can inhibit a substance contained in the adhesive layer 33 from entering the light-emitting layer 31, for example. Thus, the insulating layer 21 functions as a protective layer for the light-emitting element 30. In order to make the insulating layer 21 function as the protective layer sufficiently, it is preferable that the insulating layer 21 include a region in contact with the side surface of the insulating layer 63, the side surface of the conductive layer 60, and the side surface of the light-emitting layer 31 as well as the lens 29, specifically, the top surface of the lens 29.

With the adhesive layer 33, the substrate 11 and the substrate 12 can be bonded to each other. Specifically, the adhesive layer 33 enables the insulating layer 21 to be bonded to the coloring layer 25R, the coloring layer 25G, and the coloring layer 25B, for example. Here, the refractive index of the adhesive layer 33 is preferably lower than that of the lens 29, in which case light emitted by the light-emitting layer 31 can be condensed.

As the adhesive layer 33, an epoxy resin, an acrylic resin, a silicone resin, a phenol resin, a polyimide resin, an imide resin, a PVC (polyvinyl chloride) resin, a PVB (polyvinyl butyral) resin, an EVA (ethylene vinyl acetate) resin, or the like can be used. Alternatively, a two-component resin may be used. The adhesive layer 33 does not necessarily include a resin. For example, the adhesive layer 33 can be a vacuum layer.

The coloring layer 25R has a function of transmitting red light, for example. The coloring layer 25G has a function of transmitting green light, for example. The coloring layer 25B has a function of transmitting blue light, for example. In this case, red light is emitted from the pixel 15R, green light is emitted from the pixel 15G, and blue light is emitted from the pixel 15B. Note that the coloring layer 25R, the coloring layer 25G, or the coloring layer 25B may have a function of transmitting light of cyan, magenta, yellow, or the like. In addition, although three kinds of coloring layers are illustrated in FIG. 1, the display device 10 may include four or more kinds of coloring layers. Note that the thickness of the coloring layer 25R, the thickness of the coloring layer 25G, and the thickness of the coloring layer 25B are equal to one another in FIG. 1; however, they may be different from each other.

For the coloring layer 25R, the coloring layer 25G, and the coloring layer 25B, a metal material, a resin material, a resin material containing pigment or dye, or the like can be used.

The light-blocking layer 45 is provided between the coloring layers. FIG. 1 illustrates an example where the light-blocking layers 45 are provided between the coloring layer 25R and the coloring layer 25G and between the coloring layer 25G and the coloring layer 25B. The light-blocking layer 45 has a function of blocking light emitted from the adjacent pixel. As the light-blocking layer 45, a metal, a resin containing black pigment, carbon black, a metal oxide, a composite oxide containing a solid solution of a plurality of metal oxides, or the like can be used. Note that the display device 10 is not necessarily provided with the light-blocking layer 45. For example, when the coloring layers adjacent to each other are provided to partly overlap with each other, the overlapping portion can serve as a light-blocking layer.

As illustrated in FIG. 1, in the display device 10, the light-emitting layer 31 and the conductive layer 60 can be isolated between the pixels. This can inhibit the generation of crosstalk due to the oblique electric field caused by the conductive layer 42. Thus, high-quality images can be displayed on the display device 10. In addition, even in the case where the pixels provided in the display device 10 are miniaturized to have the pixel density increased, the generation of crosstalk can be inhibited. Thus, the display device 10 can be a high-definition display device.

### Manufacturing Method Example

An example of a manufacturing method of the display device 10 will be described below with reference to drawings.

Note that thin films that form the display device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. As the CVD method, a plasma-enhanced chemical vapor deposition (PECVD) method or a thermal CVD method may be used. As an example of the thermal CVD method, a metal organic chemical vapor deposition (MOCVD) method may be used.

The thin films that form the display device can be formed by a method such as spin coating, dipping, spray coating, ink-jetting, dispensing, screen printing, offset printing, a doctor knife, a slit coater, a roll coater, a curtain coater, and a knife coater.

When the thin films that form the display device are processed, a photolithography method or the like can be used for the processing, for example. Alternatively, island-shaped thin films may be formed by a deposition method using a blocking mask. Alternatively, the thin films may be processed by a nanoimprinting method, a sandblasting method, a lift-off method, or the like. The following two examples of a photolithography method can be given. In one method, a photosensitive resist material is applied onto a thin film to be processed and exposed to light through a photomask; development is performed to form a resist mask; the thin film is processed by etching or the like; then, the resist mask is removed. In the other method, after a photosensitive thin film is formed, exposure and development are performed, so that the thin film is processed into a desired shape.

In the case of using light in the photolithography method, for example, an i-line (a wavelength of 365 nm), a g-line (a wavelength of 436 nm), and an h-line (a wavelength of 405 nm), or combined light of any of them can be used for light exposure. Besides, ultraviolet light, KrF laser light, ArF laser light, or the like can be used. Exposure may be performed by liquid immersion exposure technique. As the light used for the exposure, extreme ultraviolet (EUV) light or X-rays may be used. Furthermore, instead of the light used for the exposure, an electron beam can also be used. It is preferable to use extreme ultra-violet light, X-rays, or an electron beam because extremely minute processing can be performed. Note that when light exposure is performed by scanning of a beam such as an electron beam, a photomask is unnecessary.

For etching of the thin films, a dry etching method, a wet etching method, a sandblast method, or the like can be used.

First, the transistor 52 is formed over the substrate 11. Next, the insulating layer 13 is formed over the substrate 11 and over the transistor 52. Then, an opening reaching the transistor 52 is formed in the insulating layer 13. Next, a conductive film that is to be the conductive layer 42 is formed over the insulating layer 13, and the conductive film is partly etched to form the conductive layer 42.

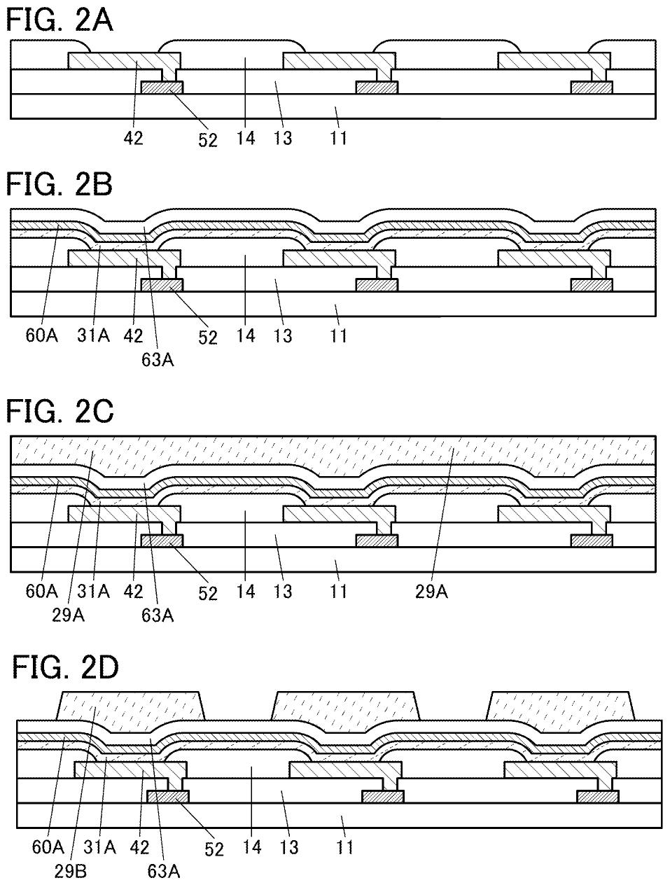

Then, the partition 14 is formed to cover the end portion of the conductive layer 42 (FIG. 2A). Next, a film 31A that is to be the light-emitting layer 31, a film 60A that is to be the conductive layer 60, and a film 63A that is to be the insulating layer 63 are formed in this order (FIG. 2B).

The film 31A can be deposited by an evaporation method, a coating method, a printing method, a discharge method, or the like. For example, an evaporation method not using a fine metal mask can be used. The film 60A can be deposited by an evaporation method, a sputtering method, or the like. The film 63A can be deposited by an ALD method, a CVD method, a sputtering method, or the like.

After that, a resist 29A is applied on the film 63A (FIG. 2C). The application of the resist 29A can be performed with a spin coating method, a spray coating method, or the like.

Next, light exposure is performed on the resist 29A, so that the resist 29A is processed. Thus, a resist mask 29B is formed (FIG. 2D). The resist mask 29B has a region overlapping with the conductive layer 42.

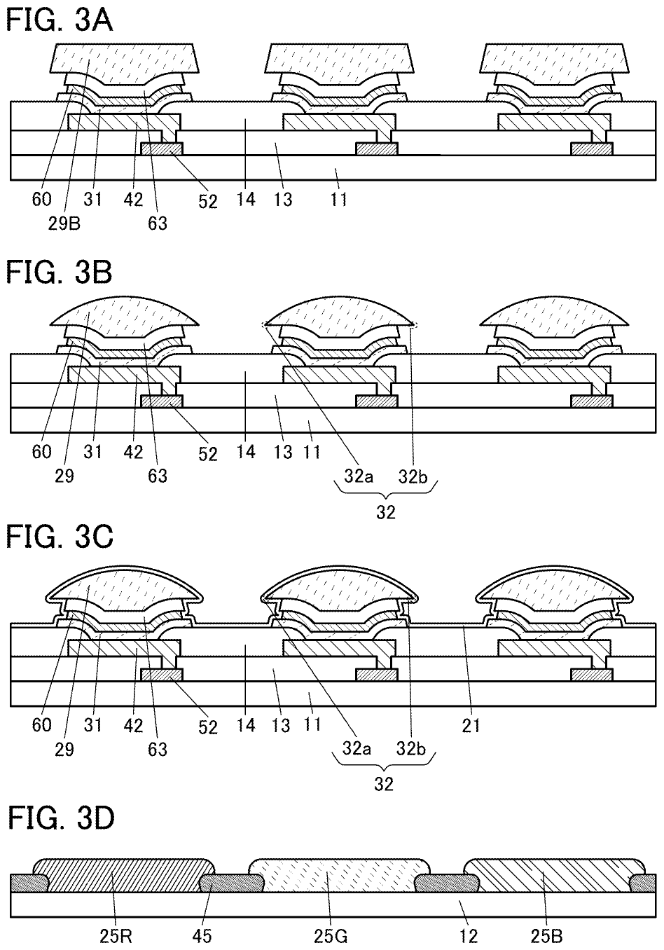

After that, the film 63A, the film 60A, and the film 31A are etched using the resist mask 29B as a mask. Thus, the island-shaped insulating layer 63, the island-shaped conductive layer 60, and the island-shaped light-emitting layer 31 are formed (FIG. 3A). As the etching, dry etching or wet etching can be used, for example.

In this step, the film 63A, the film 60A, and the film 31A are etched not only in the vertical direction but also in the horizontal direction. As a result, the end portion of the insulating layer 63, the end portion of the conductive layer 60, and the end portion of the light-emitting layer 31 can be located more inward than the end portion of the resist mask 29B. At least one of the end portion of the insulating layer 63, the end portion of the conductive layer 60, and the end portion of the light-emitting layer 31 may be located more outward than the end portion of the resist mask 29B. For example, the end portion of the light-emitting layer 31 may be located more outward than the end portion of the resist mask 29B.

Next, the substrate 11 is heated. Thus, the resist mask 29B is softened and changed in shape to be a convex. The shape change of the resist mask 29B into a convex leads to the formation of the lens 29 (FIG. 3B).

After that, the insulating layer 21 is formed over the lens 29 and the partition 14 (FIG. 3C). As described above, the insulating layer 21 is preferably formed to have a region in contact not only with the top surface of the lens 29 but also with the side surface of the insulating layer 63, the side surface of the conductive layer 60, and the side surface of the light-emitting layer 31. Moreover, as described above, the end portion 32 of the lens 29 is located more outward than the end portion of the insulating layer 63, the end portion of the conductive layer 60, and the end portion of the light-emitting layer 31. According to the above, it is preferable that the insulating layer 21 be an insulating film with favorable coverage. Therefore, the insulating layer 21 is preferably deposited by an ALD method, for example.

Next, the coloring layer 25R, the coloring layer 25G, the coloring layer 25B, and the light-blocking layer 45 are formed over the substrate 12 (FIG. 3D). After that, the insulating layer 21, the coloring layer 25R, the coloring layer 25G, the coloring layer 25B, and the light-blocking layer 45 are bonded with the adhesive layer 33. The adhesive layer 33 can be formed by a screen printing method, a dispensing method, or the like. Through the above steps, the display device 10 illustrated in FIG. 1 can be manufactured.

In the method for manufacturing a display device of one embodiment of the present invention, the island-shaped insulating layer 63, the island-shaped conductive layer 60, and the island-shaped light-emitting layer 31 are formed through etching using the resist mask 29B as a mask, and then the lens 29 is formed through heat treatment on the substrate 11. Thus, the manufacturing process can be simplified as compared with the case where the lens 29 is formed after the removal of the resist mask 29B. As described above, the display device can be manufactured by a simple method in accordance with the method for manufacturing a display device of one embodiment of the present invention. Consequently, the display device of one embodiment of the present invention can be a low-cost display device.

### Structure Example 2

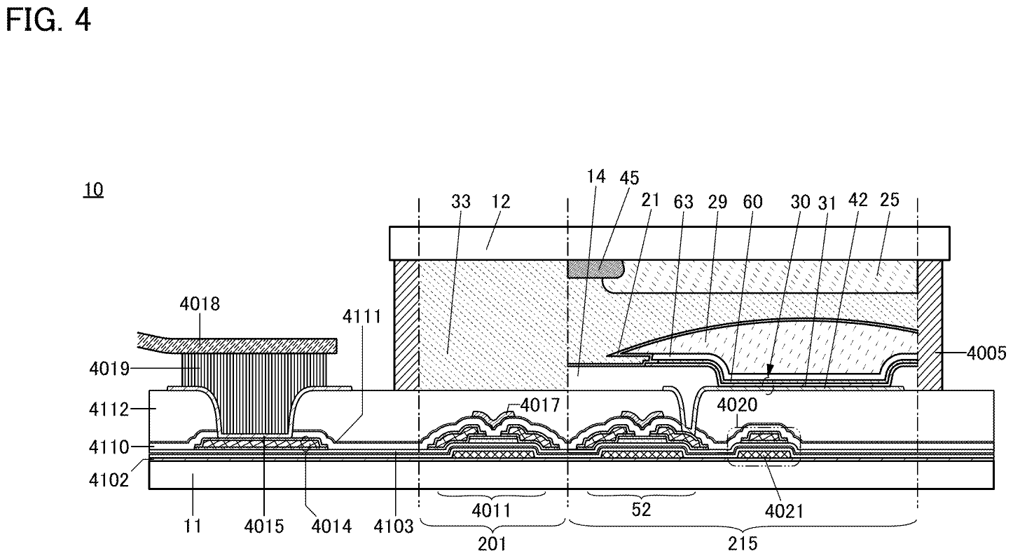

FIG. 4 is a cross-sectional view illustrating a structure example of the display device 10. FIG. 4 illustrates a specific structure example of the display device 10 illustrated in FIG. 1. The structure example in FIG. 4 includes a display portion 215, the driver circuit 201, and the like.

The display device 10 in FIG. 4 includes an electrode 4015, and the electrode 4015 is electrically connected to a terminal included in an FPC 4018 through an anisotropic conductive layer 4019. In FIG. 4, the electrode 4015 is electrically connected to a wiring 4014 in an opening formed in an insulating layer 4112, an insulating layer 4111, and an insulating layer 4110.

The electrode 4015 is formed of the same conductive layer as the conductive layer 42, and the wiring 4014 is formed of the same conductive layer as source electrodes and drain electrodes of the transistor 52 and a transistor 4011.

The display portion 215 and the driver circuit 201 provided over the substrate 11 each include a plurality of transistors. In FIG. 4, the transistor 52 included in the display portion 215 and the transistor 4011 included in the driver circuit 201 are shown as an example. In the example shown in FIG. 4, the transistor 52 and the transistor 4011 are bottom-gate transistors but may be top-gate transistors.

In FIG. 4, the insulating layer 4112 is provided over the transistor 52 and the transistor 4011. In addition, the partition 14 is formed over the insulating layer 4112.

The transistor 52 and the transistor 4011 are provided over an insulating layer 4102. The transistor 52 and the transistor 4011 each include an electrode 4017 formed over the insulating layer 4111. The electrode 4017 can serve as a back gate electrode.

The display device 10 illustrated in FIG. 4 further includes a capacitor 4020. The capacitor 4020 includes an electrode 4021 formed in the same step as a gate electrode of the transistor 52 and an electrode formed in the same step as the source electrode and the drain electrode. The electrodes overlap with each other with an insulating layer 4103 therebetween.

The display device illustrated in FIG. 4 further includes the insulating layer 4111 and the insulating layer 4102. As the insulating layer 4111 and the insulating layer 4102, insulating layers through which impurity elements do not easily pass are used. The transistor is sandwiched between the insulating layer 4111 and the insulating layer 4102, so that entry of impurities into a semiconductor layer from the outside can be prevented.

In FIG. 4, the display portion 215 and the driver circuit 201 are sealed with a sealant 4005 and the substrate 12. A glass material such as a glass frit or a resin material such as a resin that is curable at room temperature, e.g., a two-component-mixture-type resin, a light curable resin, or a thermosetting resin can be used for the sealant 4005. A drying agent may be contained in the sealant 4005.

If needed, an optical film such as a polarizing plate, a circularly polarizing plate (including an elliptically polarizing plate), or a retardation plate (a quarter-wave plate or a half-wave plate) may be provided as appropriate on a light-emitting surface of the light-emitting element 30. Furthermore, the polarizing plate or the circularly polarizing plate may be provided with an anti-reflection film. For example, anti-glare treatment by which reflected light can be diffused by projections and depressions on a surface to reduce the glare can be performed.

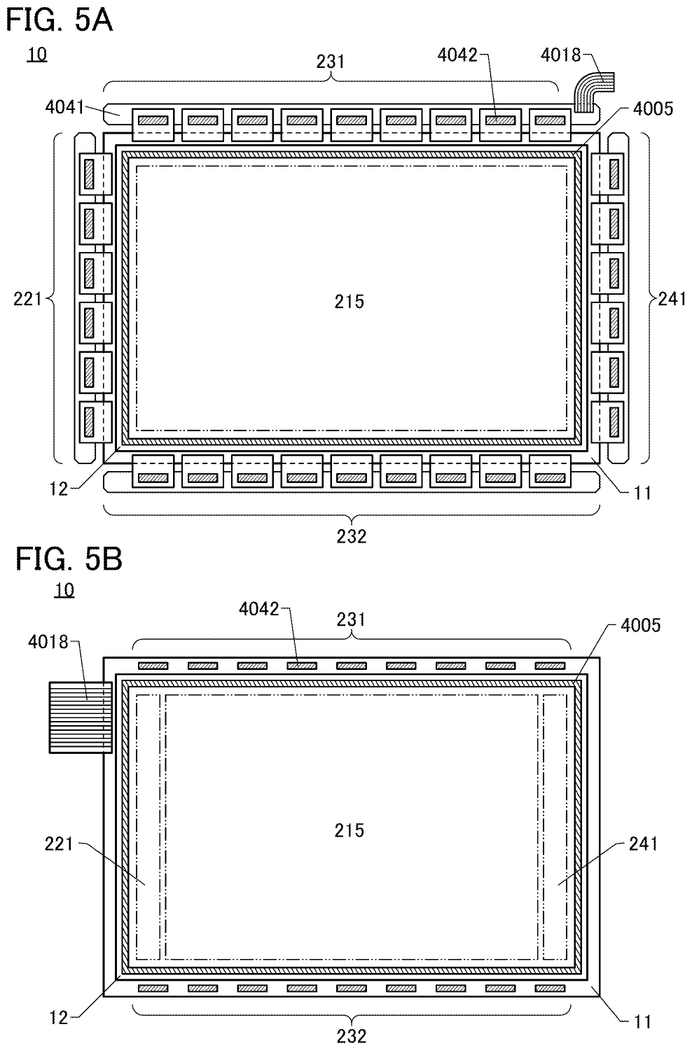

FIG. 5A and FIG. 5B are diagrams each illustrating a structure example of the display device 10. The display device 10 having the structure in FIG. 5A is provided with the sealant 4005 so as to surround the display portion 215.

In the display portion 215, pixels 15 (the pixel 15R, the pixel 15G, and the pixel 15B) illustrated in FIG. 1 and the like are arranged in a matrix.

In FIG. 5A, a driver circuit 221, a driver circuit 231, a driver circuit 232, and a driver circuit 241 each include a plurality of integrated circuits 4042 provided over a printed circuit board 4041. The integrated circuits 4042 are formed using a single crystal semiconductor or a polycrystalline semiconductor. Here, the driver circuit 201 in FIG. 4 can be the driver circuit 221, the driver circuit 231, the driver circuit 232, the driver circuit 241, or the like.

Various signals and potentials are supplied to the driver circuit 221, the driver circuit 241, the driver circuit 231, and the driver circuit 232 through an FPC (Flexible Printed Circuit) 4018.

The integrated circuits 4042 included in the driver circuit 221 and the driver circuit 241 each have a function of supplying a selection signal to the display portion 215. The integrated circuits 4042 included in the driver circuit 231 and the driver circuit 232 each have a function of supplying an image signal to the display portion 215. The integrated circuits 4042 are mounted in a region different from a region surrounded by the sealant 4005 over the substrate 11.

Note that the connection method of the integrated circuits 4042 is not particularly limited, and a wire bonding method, a COG (Chip On Glass) method, a TCP (Tape Carrier Package) method, a COF (Chip On Film) method, or the like can be used.

FIG. 5B shows an example of mounting the integrated circuits 4042 included in the driver circuit 231 and the driver circuit 232 by a COG method. Some or all of the driver circuits can be formed over the same substrate as the display portion 215, whereby a system-on-panel can be formed.

In the example shown in FIG. 5B, the driver circuit 221 and the driver circuit 241 are formed over the substrate over which the display portion 215 is formed. When the driver circuits are formed concurrently with pixel circuits in the display portion 215, the number of components can be reduced. Accordingly, the productivity can be increased.

In addition, in FIG. 5B, the sealant 4005 is provided to surround the display portion 215, the driver circuit 221 and the driver circuit 241 that are provided over the substrate 11. The substrate 12 is provided over the display portion 215, the driver circuit 221 and the driver circuit 241. Consequently, the display portion 215, the circuit 221, and the driver circuit 241 are sealed together with light-emitting elements with use of the substrate 11, the sealant 4005, and the substrate 12.

Although the driver circuit 231 and the driver circuit 232 are formed separately and mounted on the substrate 11 in the example shown in FIG. 5B, one embodiment of the present invention is not limited to this structure. For example, the driver circuit 221 may be formed separately and then mounted.

In some cases, the display device 10 includes a panel in which a light-emitting element is sealed, and a module in which an IC or the like including a controller is mounted on the panel.

An input device can be provided over the substrate 12. The structure where the display device 10 shown in FIG. 5A or FIG. 5B is provided with the input device can function as a touch panel.

There is no limitation on a detection element (also referred to as a sensor element) included in the touch panel of one embodiment of the present invention. A variety of sensors that can sense proximity or touch of a sensing target such as a finger or a stylus can be used as the sensor element.

For example, a variety of types such as a capacitive type, a resistive type, a surface acoustic wave type, an infrared type, an optical type, and a pressure-sensitive type can be used as the sensor type.

In this embodiment, a touch panel including a capacitive detection element is described as an example.

Examples of the capacitive type include a surface capacitive type and a projected capacitive type. Examples of the projected capacitive type include a self-capacitive type and a mutual capacitive type. The use of a mutual capacitive type is preferred because multiple points can be sensed simultaneously.

The touch panel of one embodiment of the present invention can have any of a variety of structures, including a structure in which a display device and a detection element that are separately formed are attached to each other and a structure in which an electrode and the like included in a detection element are provided on one or both of a substrate supporting a light-emitting element and a counter substrate.

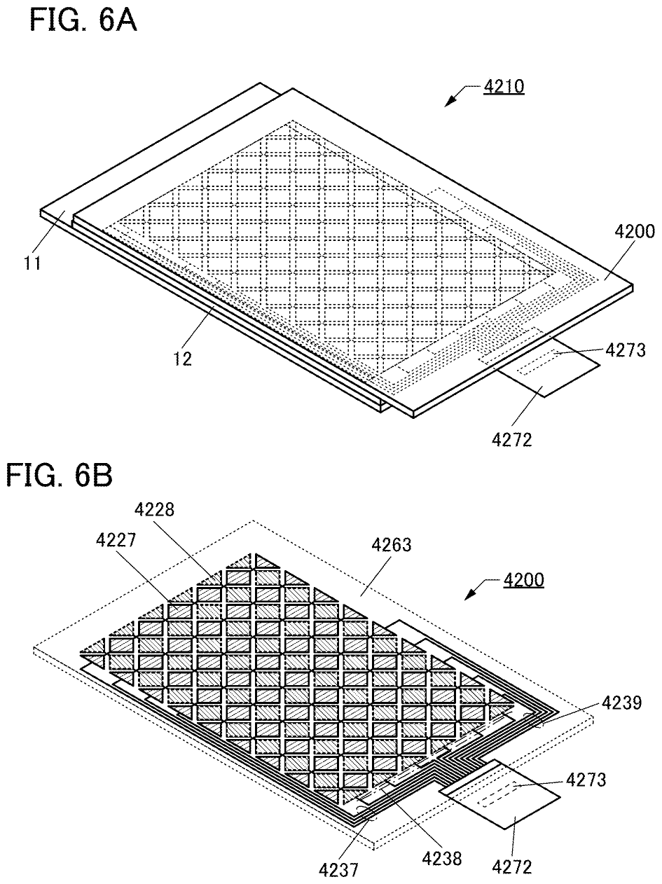

FIG. 6A and FIG. 6B illustrate an example of the touch panel. FIG. 6A is a perspective view of a touch panel 4210. The touch panel 4210 includes an input device 4200. FIG. 6B is a schematic perspective view of the input device 4200. Note that for clarity, only typical components are illustrated.

The touch panel 4210 has a structure in which a display device and a detection element that are separately manufactured are attached to each other.

The touch panel 4210 includes the input device 4200 and the display device 10, which are provided to overlap with each other. Note that the display device 10 is not illustrated in FIG. 6A.

The input device 4200 includes a substrate 4263, an electrode 4227, an electrode 4228, a plurality of wirings 4237, a plurality of wirings 4238, and a plurality of wirings 4239. For example, the electrode 4227 can be electrically connected to the wiring 4237 or the wiring 4239. In addition, the electrode 4228 can be electrically connected to the wiring 4239. An FPC 4272 is electrically connected to each of the plurality of wirings 4237, the plurality of wirings 4238, and the plurality of wirings 4239. An IC 4273 can be provided for the FPC 4272.

Alternatively, a touch sensor may be provided between the substrate 11 and the substrate 12 in the display device 10. When a touch sensor is provided between the substrate 11 and the substrate 12, an optical touch sensor using a photoelectric conversion element as a detection element may be used other than a capacitive touch sensor.

At least part of this embodiment can be implemented in appropriate combination with the other embodiments described in this specification.

### Embodiment 2

In this embodiment, a structure of a transistor that can be used in the display device of one embodiment of the present invention will be described.

The display device of one embodiment of the present invention can be fabricated using a transistor with any of various structures, such as a bottom-gate transistor and a top-gate transistor. Therefore, the material of a semiconductor layer and the structure of a transistor can be easily changed depending on the existing production line.

### [Bottom-Gate Transistor]

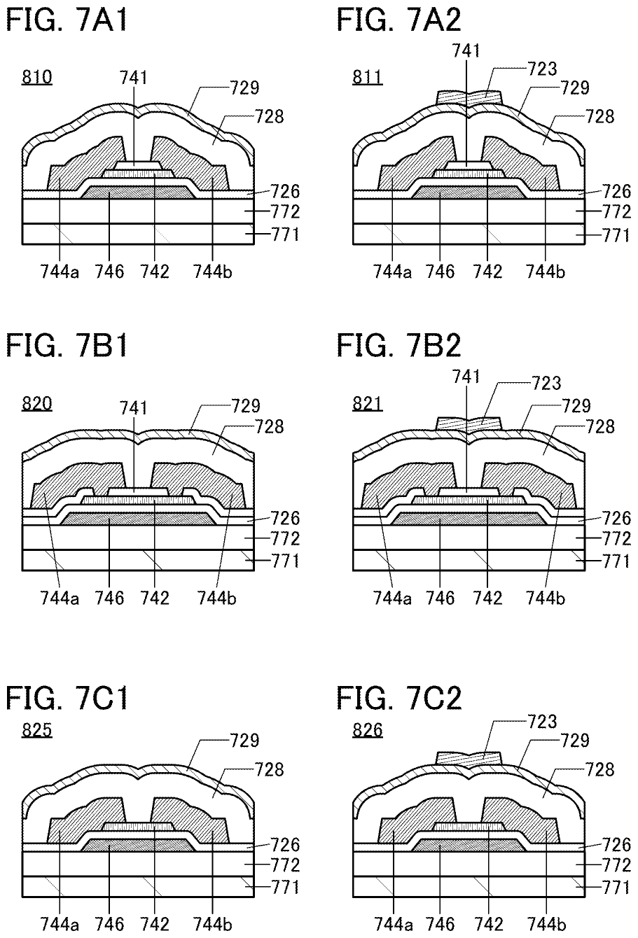

FIG. 7A1 is a cross-sectional view of a channel protective transistor 810 that is a type of bottom-gate transistor. In FIG. 7A1, the transistor 810 is formed over a substrate 771. In addition, the transistor 810 includes an electrode 746 over the substrate 771 with an insulating layer 772 therebetween. The transistor 810 further includes a semiconductor layer 742 over the electrode 746 with an insulating layer 726 therebetween. The electrode 746 can function as a gate electrode. The insulating layer 726 can function as a gate insulating layer.

In addition, an insulating layer 741 is provided over a channel formation region in the semiconductor layer 742. Furthermore, an electrode 744a and an electrode 744b are included over the insulating layer 726 to be partly in contact with the semiconductor layer 742. The electrode 744a can function as one of a source electrode and a drain electrode. The electrode 744b can function as the other of the source electrode and the drain electrode. Part of the electrode 744a and part of the electrode 744b are formed over the insulating layer 741.

The insulating layer 741 can function as a channel protective layer. With the insulating layer 741 provided over the channel formation region, the semiconductor layer 742 can be prevented from being exposed at the time of forming the electrode 744a and the electrode 744b. Thus, the channel formation region in the semiconductor layer 742 can be prevented from being etched at the time of forming the electrode 744a and the electrode 744b. According to one embodiment of the present invention, a transistor with favorable electrical characteristics can be achieved.

The transistor 810 includes an insulating layer 728 over the electrode 744a, the electrode 744b, and the insulating layer 741 and also includes an insulating layer 729 over the insulating layer 728.

In the case where an oxide semiconductor is used for the semiconductor layer 742, a material capable of removing oxygen from part of the semiconductor layer 742 to generate oxygen vacancies is preferably used at least for portions of the electrode 744a and the electrode 744b that are in contact with the semiconductor layer 742. In a region where oxygen vacancies are generated in the semiconductor layer 742, the carrier concentration is increased; thus, the region becomes to have n-type conductivity to be an n-type region (n⁺ layer). Accordingly, the regions can function as a source region or a drain region. When an oxide semiconductor is used for the semiconductor layer 742, examples of the material capable of removing oxygen from the semiconductor layer 742 to generate oxygen vacancies include tungsten and titanium.

Formation of the source region and the drain region in the semiconductor layer 742 makes it possible to reduce contact resistance between the semiconductor layer 742 and each of the electrode 744a and the electrode 744b. Accordingly, the electrical characteristics of the transistor, such as the field-effect mobility and the threshold voltage, can become favorable.

In the case where a semiconductor such as silicon is used for the semiconductor layer 742, a layer that functions as an n-type semiconductor or a p-type semiconductor is preferably provided between the semiconductor layer 742 and the electrode 744a and between the semiconductor layer 742 and the electrode 744b. The layer that functions as an n-type semiconductor or a p-type semiconductor can function as the source region or the drain region of the transistor.

The insulating layer 729 is preferably formed using a material that has a function of preventing or reducing diffusion of impurities into the transistor from the outside. Note that the insulating layer 729 can be omitted as necessary.

A transistor 811 illustrated in FIG. 7A2 is different from the transistor 810 in that an electrode 723 that can function as a back gate electrode is provided over the insulating layer 729. The electrode 723 can be formed using a material and a method similar to those of the electrode 746.

In general, a back gate electrode is formed using a conductive layer and positioned so that a channel formation region in a semiconductor layer is sandwiched between the gate electrode and the back gate electrode. Thus, the back gate electrode can function in a manner similar to that of the gate electrode. The potential of the back gate electrode may be the same as the potential of the gate electrode, may be a ground potential (GND potential), or may be a given potential. In addition, when the potential of the back gate electrode is changed without synchronization and independently of the potential of the gate electrode, the threshold voltage of the transistor can be changed.

The electrode 746 and the electrode 723 can both function as a gate electrode. Thus, the insulating layer 726, the insulating layer 728, and the insulating layer 729 can each function as a gate insulating layer. Note that the electrode 723 may be provided between the insulating layer 728 and the insulating layer 729.

Note that in the case where one of the electrode 746 and the electrode 723 is referred to as a “gate electrode”, the other is referred to as a “back gate electrode”. For example, in the case where the electrode 723 in the transistor 811 is referred to as a “gate electrode”, the electrode 746 is referred to as a “back gate electrode”. In the case where the electrode 723 is used as a “gate electrode”, the transistor 811 can be considered as a type of top-gate transistor. One of the electrode 746 and the electrode 723 may be referred to as a “first gate electrode”, and the other may be referred to as a “second gate electrode”.

By providing the electrode 746 and the electrode 723 with the semiconductor layer 742 sandwiched therebetween and setting the potentials of the electrode 746 and the electrode 723 to the same potential, a region of the semiconductor layer 742 through which carriers flow is enlarged in the film thickness direction; thus, the amount of carrier transfer is increased. As a result, the on-state current of the transistor 811 increases and the field-effect mobility increases.

Therefore, the transistor 811 is a transistor having a high on-state current for its occupied area. That is, the area occupied by the transistor 811 can be small for a required on-state current. According to one embodiment of the present invention, the area occupied by a transistor can be reduced. Hence, according to one embodiment of the present invention, a display device including minute pixels can be achieved, which leads to an achievement of a high-definition display device.

In addition, the gate electrode and the back gate electrode are formed using conductive layers and thus each have a function of preventing an electric field generated outside the transistor from affecting the semiconductor layer in which the channel is formed (in particular, for example, an electric field blocking function against static electricity and the like). Note that when the back gate electrode is formed larger than the semiconductor layer so that the semiconductor layer is covered with the back gate electrode, the electric field blocking function can be enhanced.

Furthermore, when the back gate electrode is formed using a light-blocking conductive film, light can be prevented from entering the semiconductor layer from the back gate electrode side. Therefore, photodegradation of the semiconductor layer can be prevented, and deterioration in electrical characteristics of the transistor, such as a shift of the threshold voltage, can be prevented.

According to one embodiment of the present invention, a transistor with favorable reliability can be achieved. Moreover, a display device with favorable reliability can be achieved.

FIG. 7B1 is a cross-sectional view of a channel-protective transistor 820 that is a type of bottom-gate transistor. The transistor 820 has substantially the same structure as the transistor 810 but is different from the transistor 810 in that the insulating layer 741 covers end portions of the semiconductor layer 742. In addition, the semiconductor layer 742 is electrically connected to the electrode 744a through an opening portion formed by selectively removing part of the insulating layer 741 that overlaps with the semiconductor layer 742. Furthermore, the semiconductor layer 742 is electrically connected to the electrode 744b through another opening portion formed by selectively removing part of the insulating layer 741 that overlaps with the semiconductor layer 742. A region of the insulating layer 741 that overlaps with the channel formation region can function as a channel protective layer.

A transistor 821 illustrated in FIG. 7B2 is different from the transistor 820 in that the electrode 723 that can function as a back gate electrode is provided over the insulating layer 729.

With the insulating layer 741, the semiconductor layer 742 can be prevented from being exposed at the time of forming the electrode 744a and the electrode 744b. Thus, the semiconductor layer 742 can be prevented from being reduced in thickness at the time of forming the electrode 744a and the electrode 744b.

The distance between the electrode 744a and the electrode 746 and the distance between the electrode 744b and the electrode 746 are longer in the transistor 820 and the transistor 821 than in the transistor 810 and the transistor 811. Thus, parasitic capacitance generated between the electrode 744a and the electrode 746 can be reduced. Moreover, parasitic capacitance generated between the electrode 744b and the electrode 746 can be reduced. According to one embodiment of the present invention, a transistor with favorable electrical characteristics can be achieved.

A transistor 825 illustrated in FIG. 7C1 is a channel-etched transistor that is a type of bottom-gate transistor. In the transistor 825, the electrode 744a and the electrode 744b are formed without using the insulating layer 741. Thus, part of the semiconductor layer 742 that is exposed at the time of forming the electrode 744a and the electrode 744b is etched in some cases. However, since the insulating layer 741 is not provided, the productivity of the transistor can be increased.

A transistor 826 illustrated in FIG. 7C2 is different from the transistor 820 in that the electrode 723 that can function as a back gate electrode is provided over the insulating layer 729.

### [Top-Gate Transistor]

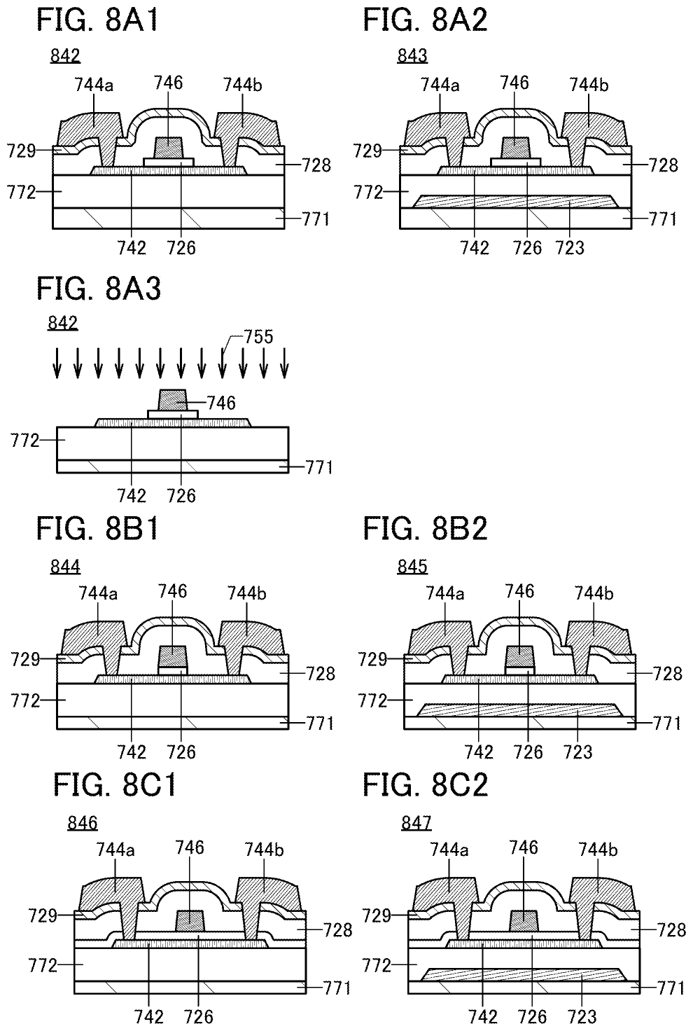

A transistor 842 illustrated in FIG. 8A1 as an example is a type of top-gate transistor. The transistor 842 is different from the transistor 810, the transistor 811, the transistor 820, the transistor 821, the transistor 825, and the transistor 826 in that the electrode 744a and the electrode 744b are formed after the formation of the insulating layer 729. The electrode 744a and the electrode 744b are electrically connected to the semiconductor layer 742 in openings formed in the insulating layer 728 and the insulating layer 729.

A transistor 843 illustrated in FIG. 8A2 is different from the transistor 842 in that the electrode 723 is included. The transistor 843 includes the electrode 723 that is formed over the substrate 771. The electrode 723 includes a region overlapping with the semiconductor layer 742 with the insulating layer 772 therebetween. The electrode 723 can function as a back gate electrode.

Furthermore, as illustrated in FIG. 8A3, part of the insulating layer 726 that does not overlap with the electrode 746 is removed, and an impurity 755 is introduced into the semiconductor layer 742 using the electrode 746 and the residual insulating layer 726 as masks in a manufacturing step of the transistor 842, so that an impurity region can be formed in the semiconductor layer 742 in a self-aligned manner. The transistor 842 includes a region where the insulating layer 726 extends beyond end portions of the electrode 746. The semiconductor layer 742 in a region into which the impurity 755 is introduced through the insulating layer 726 has a lower impurity concentration than a region into which the impurity 755 is introduced without through the insulating layer 726. Thus, an LDD (Lightly Doped Drain) region is formed in a region of the semiconductor layer 742 that does not overlap with the electrode 746. The same applies to the transistor 843.

As in a transistor 844 illustrated in FIG. 8B1 and a transistor 845 illustrated in FIG. 8B2, the insulating layer 726 in a region that does not overlap with the electrode 746 may be completely removed. Alternatively, as in a transistor 846 illustrated in FIG. 8C1 and a transistor 847 illustrated in FIG. 8C2, the insulating layer 726 may be left.

Also in the transistor 844 to the transistor 847, the impurity 755 is introduced into the semiconductor layer 742 using the electrode 746 as a mask after the formation of the electrode 746, so that an impurity region can be formed in the semiconductor layer 742 in a self-aligned manner. According to one embodiment of the present invention, a transistor with favorable electrical characteristics can be achieved. According to one embodiment of the present invention, a high-definition display device can be achieved.

At least part of this embodiment can be implemented in appropriate combination with the other embodiments described in this specification.

### Embodiment 3

In this embodiment, an example of a head-mounted display including a display device will be described as an example of an electronic device of one embodiment of the present invention.

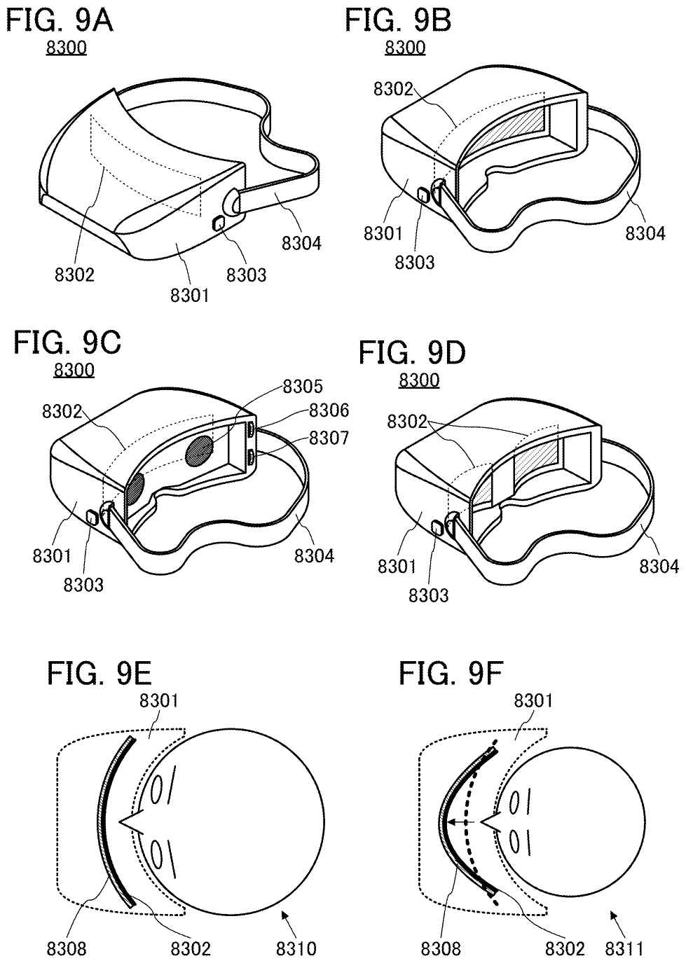

FIG. 9A and FIG. 9B each show an external view of a head-mounted display 8300.

The head-mounted display 8300 includes a housing 8301, a display portion 8302, an operation button 8303, and a band-shaped fixing unit 8304.

The operation button 8303 functions as a power button, for example. A button other than the operation button 8303 may be included.

As illustrated in FIG. 9C, lenses 8305 may be provided between the display portion 8302 and the user's eyes. The user can see magnified images on the display portion 8302 through the lenses 8305, leading to higher sense of presence. In that case, as illustrated in FIG. 9C, a dial 8306 for changing the position of the lenses and adjusting visibility may be included.

The display device of one embodiment of the present invention can be used for the display portion 8302. Since the display device of one embodiment of the present invention has an extremely high definition, even when an image is magnified using the lenses 8305 as illustrated in FIG. 9C, the pixels are not perceived by the user, and thus a more realistic image can be displayed.

FIG. 9A to FIG. 9C show an example in which one display portion 8302 is provided. This structure can reduce the number of components.

The display portion 8302 can display an image for the right eye and an image for the left eye side by side on a right region and a left region, respectively. Thus, a three-dimensional image using binocular disparity can be displayed.

One image which can be seen by both eyes may be displayed on all over the display portion 8302. A panorama image can thus be displayed from end to end of the field of view, which can provide a higher sense of reality.

Here, the head-mounted display 8300 preferably has a mechanism for optimizing the curvature of the display portion 8302 in accordance with the size of the user's head, the position of the user's eyes, or the like. For example, the user himself/herself may adjust the curvature of the display portion 8302 by twisting a dial 8307 for adjusting the curvature of the display portion 8302. Alternatively, the head-mounted display 8300 may include a sensor for detecting the size of the user's head, or the position of the user's eyes (e.g., a camera, a contact sensor, and a noncontact sensor) on the housing 8301 and have a mechanism for adjusting the curvature of the display portion 8302 on the basis of data detected by the sensor.

In the case where the lenses 8305 are used, the head-mounted display 8300 preferably has a mechanism for adjusting the position and angle of the lenses 8305 in synchronization with the curvature of the display portion 8302. Alternatively, the dial 8306 may have a function of adjusting the angle of the lenses.

FIG. 9E and FIG. 9F show an example of including a driver portion 8308 that controls the curvature of the display portion 8302. The driver portion 8308 is fixed to at least a part of the display portion 8302. The driver portion 8308 has a function of changing the shape of the display portion 8302 when the part of the driver portion 8308 that is fixed to the display portion 8302 changes in shape or moves.

FIG. 9E is a schematic view showing the case where a user 8310 having a relatively large head wears the housing 8301. In that case, the driver portion 8308 adjusts the shape of the display portion 8302 so that the curvature is relatively small (the radius of curvature is large).

In contrast, FIG. 9F shows the case where a user 8311 having a smaller head than the user 8310 wears the housing 8301. The user 8311 has a shorter distance between the eyes than the user 8310. In that case, the driver portion 8308 adjusts the shape of the display portion 8302 so that the curvature of the display portion 8302 is large (the radius of curvature is small). In FIG. 9F, the position and shape of the display portion 8302 in FIG. 9E are denoted by a dashed line.

When the head-mounted display 8300 has such a mechanism for adjusting the curvature of the display portion 8302, an optimal display can be offered to a variety of users of all ages and genders.

When the curvature of the display portion 8302 is changed in accordance with contents displayed on the display portion 8302, the user can have a higher sense of presence. For example, shaking can be expressed by vibrating the curvature of the display portion 8302. In this way, it is possible to produce various effects according to the scene in contents, and provide the user with new experiences. Further realistic display can be provided in conjunction with a vibration module provided in the housing 8301.

Note that the head-mounted display 8300 may include two display portions 8302 as shown in FIG. 9D.

Since the head-mounted display 8300 includes the two display portions 8302, the user's eyes can see their respective display portions. This allows a high-definition image to be displayed even when three-dimensional display using parallax or the like is performed. In addition, the display portion 8302 is curved around an arc with the user's eye as an approximate center. This keeps a certain distance between the user's eye and the display surface of the display portion, enabling the user to see a more natural image. Even when the luminance or chromaticity of light from the display portion is changed depending on the angle at which the user see it, since the user's eye is positioned in a normal direction of the display surface of the display portion, the influence of the change can be substantially ignorable and thus a more realistic image can be displayed. Thus, the display portion 8302 can display a more realistic image.

At least part of this embodiment can be implemented in appropriate combination with the other embodiments described in this specification.

### Embodiment 4

In this embodiment, a display module that can be fabricated using one embodiment of the present invention is described.

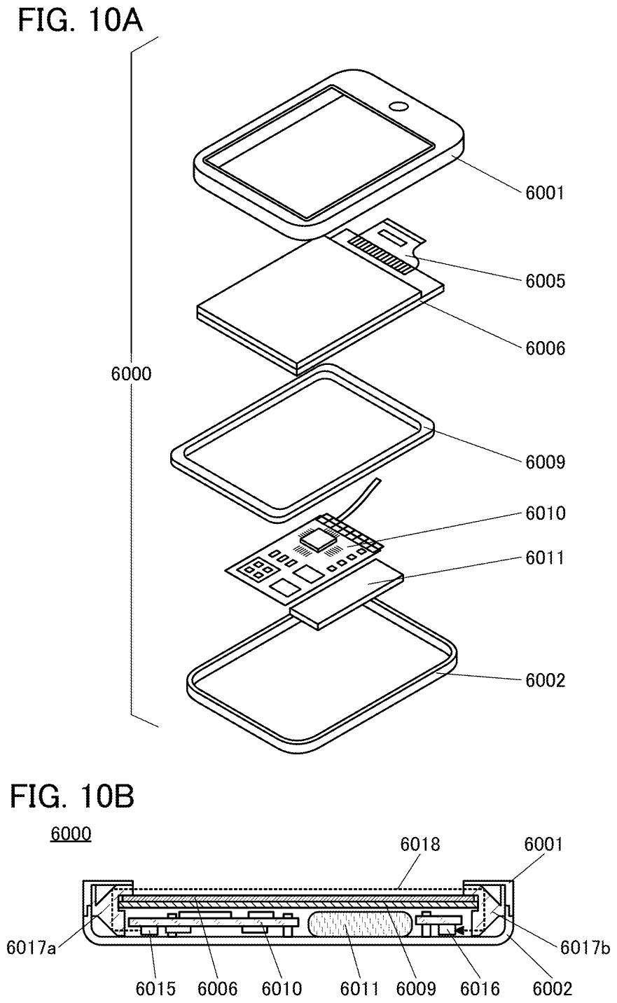

In a display module 6000 illustrated in FIG. 10A, a display device 6006 to which an FPC 6005 is connected, a frame 6009, a printed circuit board 6010, and a battery 6011 are provided between an upper cover 6001 and a lower cover 6002.

A display device fabricated using one embodiment of the present invention can be used as the display device 6006, for example. With the display device 6006, a display module with extremely low power consumption can be achieved.

The shape and size of the upper cover 6001 and the lower cover 6002 can be changed as appropriate in accordance with the size of the display device 6006.

The display device 6006 may have a function of a touch panel.

The frame 6009 may have a function of protecting the display device 6006, a function of blocking electromagnetic waves generated by the operation of the printed circuit board 6010, a function of a heat dissipation plate, or the like.

The printed circuit board 6010 includes a power supply circuit, a signal processing circuit for outputting a video signal and a clock signal, a battery control circuit, and the like.

FIG. 10B is a schematic cross-sectional view of the display module 6000 having an optical touch sensor.

The display module 6000 includes a light-emitting portion 6015 and a light-receiving portion 6016 that are provided on the printed circuit board 6010. Furthermore, a pair of light guide portions (a light guide portion 6017a and a light guide portion 6017b) are provided in regions surrounded by the upper cover 6001 and the lower cover 6002.

The display device 6006 overlaps with the printed circuit board 6010, the battery 6011, and the like with the frame 6009 therebetween. The display device 6006 and the frame 6009 are fixed to the light guide portion 6017a and the light guide portion 6017b.

Light 6018 emitted from the light-emitting portion 6015 travels over the display device 6006 through the light guide portion 6017a and reaches the light-receiving portion 6016 through the light guide portion 6017b. For example, blocking of the light 6018 by a sensing target such as a finger or a stylus enables detection of touch operation.

A plurality of light-emitting portions 6015 are provided along two adjacent sides of the display device 6006, for example. A plurality of light-receiving portions 6016 are provided at the positions on the opposite side of the light-emitting portions 6015. Accordingly, information about the position of touch operation can be obtained.

As the light-emitting portion 6015, a light source such as an LED element can be used, for example, and it is particularly preferable to use a light source emitting infrared rays. As the light-receiving portion 6016, a photoelectric conversion element that receives light emitted from the light-emitting portion 6015 and converts it into an electric signal can be used. A photodiode that can receive infrared rays can be suitably used.

With use of the light guide portion 6017a and the light guide portion 6017b that transmit the light 6018, the light-emitting portion 6015 and the light-receiving portion 6016 can be placed under the display device 6006, and a malfunction of the touch sensor due to external light reaching the light-receiving portion 6016 can be inhibited. Particularly when a resin that absorbs visible light and transmits infrared rays is used, a malfunction of the touch sensor can be inhibited more effectively.

At least part of this embodiment can be implemented in appropriate combination with the other embodiments described in this specification.

### Embodiment 5

In this embodiment, examples of an electronic device for which the display device of one embodiment of the present invention can be used will be described.

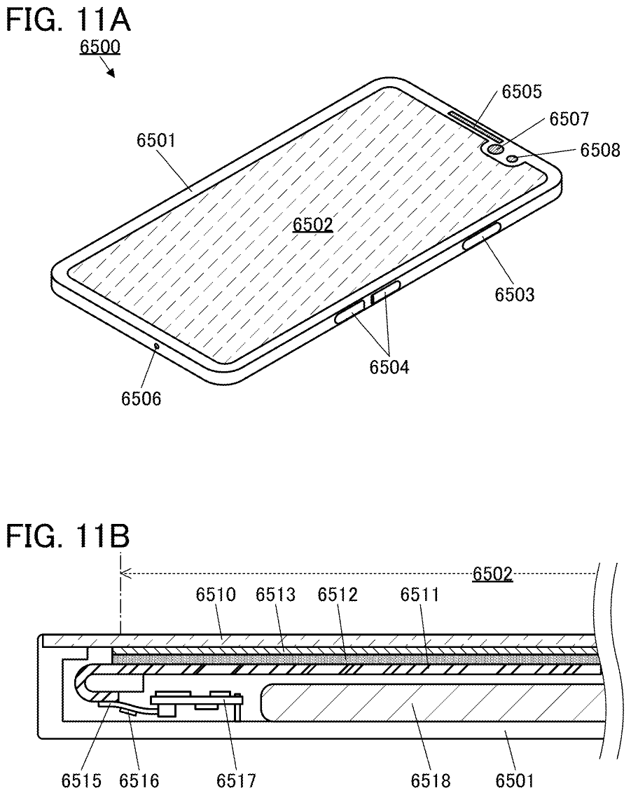

An electronic device 6500 illustrated in FIG. 11A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a high-quality image can be displayed on the display portion 6502.

FIG. 11B is a schematic cross-sectional view including an end portion of the housing 6501 on the microphone 6506 side.

A protective member 6510 having a light-transmitting property is provided on the display surface side of the housing 6501, and a display panel 6511, an optical member 6512, a touch sensor panel 6513, a printed circuit board 6517, a battery 6518, and the like are provided in a space surrounded by the housing 6501 and the protective member 6510.

The display panel 6511, the optical member 6512, and the touch sensor panel 6513 are fixed to the protective member 6510 with a bonding layer not illustrated.

Part of the display panel 6511 is bent in a region outside the display portion 6502. An FPC 6515 is connected to the bent part. An IC 6516 is mounted on the FPC 6515. The FPC 6515 is connected to a terminal provided for the printed circuit board 6517.

At least part of this embodiment can be implemented in appropriate combination with the other embodiments described in this specification.

### Embodiment 6

In this embodiment, electronic devices each including a display device fabricated using one embodiment of the present invention will be described.

Electronic devices described below as examples each include a display device of one embodiment of the present invention in a display portion. Thus, the electronic devices achieve high resolution. In addition, the electronic devices can each achieve both high resolution and a large screen.

One embodiment of the present invention includes the display device and at least one of an antenna, a battery, a housing, a camera, a speaker, a microphone, a touch sensor, and an operation button.

The electronic device of one embodiment of the present invention may include a secondary battery, and it is preferable that the secondary battery be capable of being charged by contactless power transmission.

Examples of the secondary battery include a lithium ion secondary battery such as a lithium polymer battery using a gel electrolyte (lithium ion polymer battery), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, the electronic device can display a video, data, or the like on a display portion. When the electronic device includes the antenna and a secondary battery, the antenna may be used for contactless power transmission.

A display portion in an electronic device of one embodiment of the present invention can display an image with a resolution of, for example, full high definition, 4K2K, 8K4K, 16K8K, or higher.

Examples of the electronic devices include a digital camera, a digital video camera, a digital photo frame, a cellular phone, a portable game machine, a portable information terminal, and an audio reproducing device, in addition to electronic devices with comparatively large screens, such as a television device, a notebook personal computer, a monitor device, digital signage, a pachinko machine, and a game machine.

The electronic device using one embodiment of the present invention can be incorporated along a flat surface or a curved surface of an inside wall or an outside wall of a house or a building, an interior or an exterior of a car, or the like.

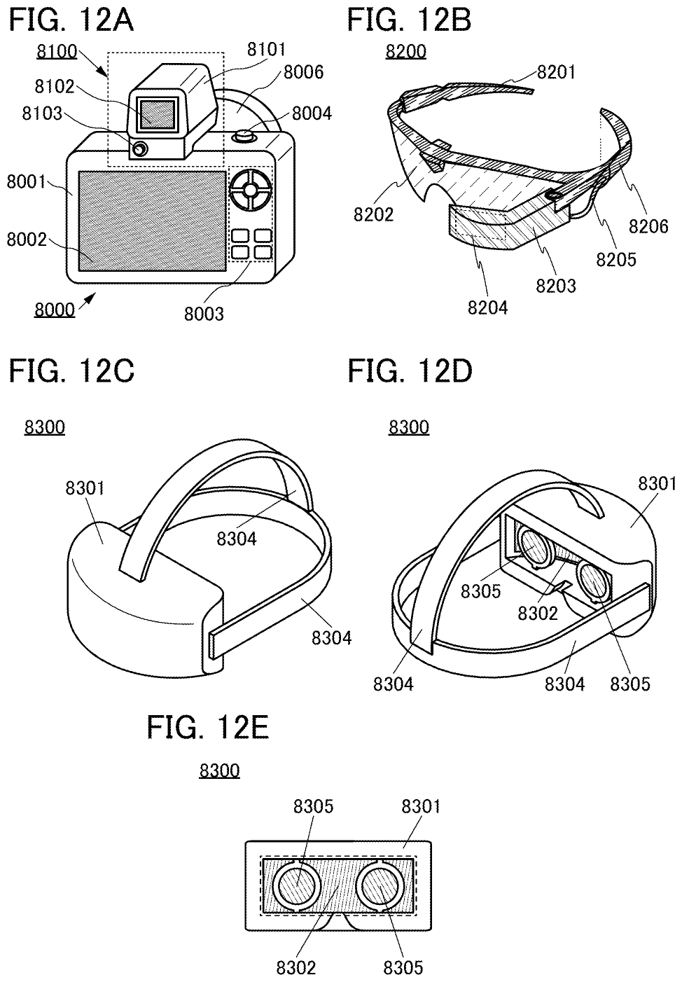

FIG. 12A is a diagram illustrating appearance of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000.

Note that the lens 8006 and the housing may be integrated with each other in the camera 8000.

The camera 8000 can take images by the press of the shutter button 8004 or touch on the display portion 8002 serving as a touch panel.

The housing 8001 includes a mount including an electrode, so that the finder 8100, a stroboscope, or the like can be connected to the housing.

The finder 8100 includes a housing 8101, a display portion 8102, a button 8103, and the like.

The housing 8101 is attached to the camera 8000 with the mount engaging with a mount of the camera 8000. In the finder 8100, a video or the like received from the camera 8000 can be displayed on the display portion 8102.

The button 8103 functions as a power button, for example.

The display device of one embodiment of the present invention can be used for the display portion 8002 of the camera 8000 and the display portion 8102 of the finder 8100. Thus, a high-quality image can be displayed on the display portion 8002 and the display portion 8102. Note that a finder may be incorporated in the camera 8000.

FIG. 12B is a diagram illustrating appearance of a head-mounted display 8200.

The head-mounted display 8200 includes a mounting portion 8201, a lens 8202, a main body 8203, a display portion 8204, a cable 8205, and the like. In addition, a battery 8206 is incorporated in the mounting portion 8201.

The cable 8205 supplies power from the battery 8206 to the main body 8203. The main body 8203 includes a wireless receiver or the like and can display received video information on the display portion 8204. The main body 8203 is provided with a camera, and information on the movement of the user's eyeball and eyelid can be used as an input means.

The mounting portion 8201 may be provided with a plurality of electrodes capable of sensing current flowing in response to the movement of the user's eyeball in a position in contact with the user to have a function of recognizing the user's sight line. Furthermore, the mounting portion 8201 may have a function of monitoring the user's pulse with use of current flowing through the electrodes. The mounting portion 8201 may include various sensors such as a temperature sensor, a pressure sensor, and an acceleration sensor to have a function of displaying the user's biological information on the display portion 8204 or a function of changing a video displayed on the display portion 8204 in accordance with the movement of the user's head.

The display device of one embodiment of the present invention can be used for the display portion 8204. Thus, a high-quality image can be displayed on the display portion 8204.

FIG. 12C, FIG. 12D, and FIG. 12E are diagrams illustrating appearance of the head-mounted display 8300. The head-mounted display 8300 includes the housing 8301, the display portion 8302, the band-shaped fixing units 8304, and a pair of lenses 8305.

A user can see display on the display portion 8302 through the lenses 8305. Note that the display portion 8302 is preferably curved and placed because the user can feel a high sense of presence. In addition, when another image displayed on a different region of the display portion 8302 is viewed through the lenses 8305, three-dimensional display using parallax or the like can also be performed. Note that the number of display portions 8302 provided is not limited to one; two display portions 8302 may be provided so that one display portion is provided for one eye of the user.

Note that the display device of one embodiment of the present invention can be used in the display portion 8302. The display device including the semiconductor device of one embodiment of the present invention has an extremely high resolution; thus, even when a video is magnified by the lenses 8305 as in FIG. 12E, the user does not perceive pixels, and a more realistic video can be displayed.

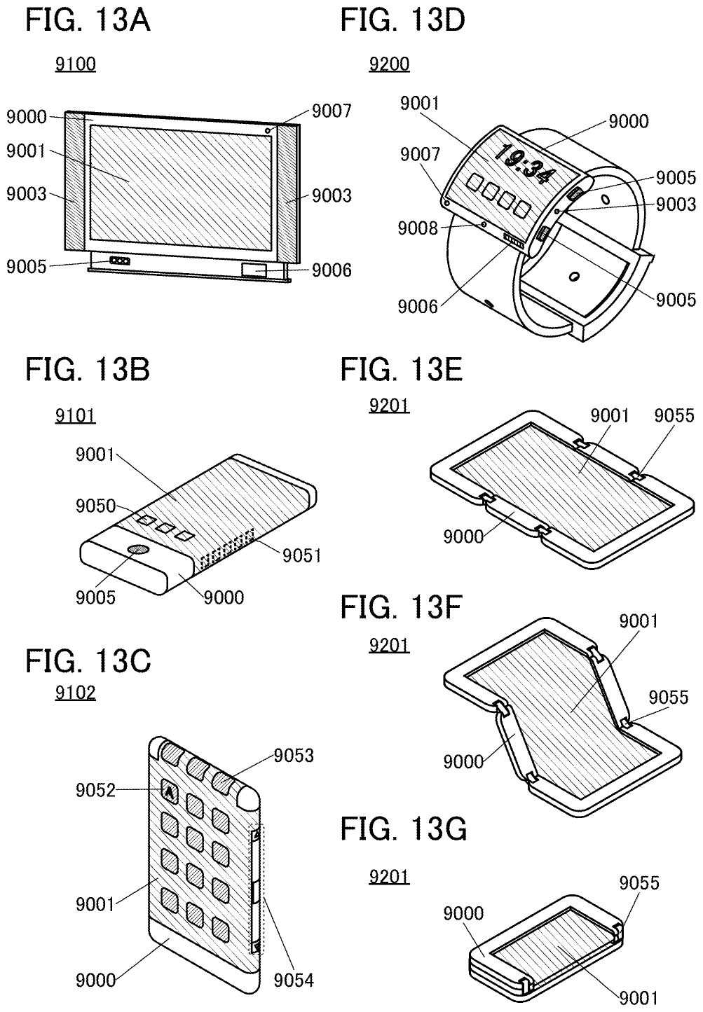

Electronic devices illustrated in FIG. 13A to FIG. 13G include a housing 9000, a display portion 9001, a speaker 9003, an operation key 9005 (including a power switch or an operation switch), a connection terminal 9006, a sensor 9007 (a sensor having a function of measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic devices illustrated in FIG. 13A to FIG. 13G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each include a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 13A to FIG. 13G are described below.

FIG. 13A is a perspective view illustrating a television device 9100. The television device 9100 can include the display portion 9001 having a large screen size of, for example, 50 inches or more, or 100 inches or more.

FIG. 13B is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display letters, image information, and the like on its plurality of surfaces. FIG. 13B illustrates an example in which three icons 9050 are displayed. Information 9051 indicated by dashed rectangles can be displayed on another surface of the display portion 9001. Examples of the information 9051 include notification of reception of an e-mail, SNS, an incoming call, or the like, the title and sender of an e-mail, SNS, or the like, the date, the time, remaining battery, and the reception strength of an antenna. Alternatively, the icon 9050 or the like may be displayed at the position where the information 9051 is displayed.

FIG. 13C is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer a call, for example.

FIG. 13D is a perspective view illustrating a watch-type portable information terminal 9200. The portable information terminal 9200 can be used as a smartwatch (registered trademark), for example. The display surface of the display portion 9001 is curved and provided, and display can be performed along the curved display surface. Mutual communication between the portable information terminal 9200 and, for example, a headset capable of wireless communication enables hands-free calling. With the connection terminal 9006, the portable information terminal 9200 can perform mutual data transmission with another information terminal or charging. Note that the charging operation may be performed by wireless power feeding.

FIG. 13E, FIG. 13F, and FIG. 13G are perspective views illustrating a foldable portable information terminal 9201. In addition, FIG. 13E is a perspective view of an unfolded state of the portable information terminal 9201, FIG. 13G is a perspective view of a folded state thereof, and FIG. 13F is a perspective view of a state in the middle of change from one of FIG. 13E and FIG. 13G to the other. The portable information terminal 9201 is highly portable in the folded state and is highly browsable in the unfolded state because of a seamless large display region. The display portion 9001 of the portable information terminal 9201 is supported by three housings 9000 joined by hinges 9055. For example, the display portion 9001 can be bent with a radius of curvature greater than or equal to 1 mm and less than or equal to 150 mm.

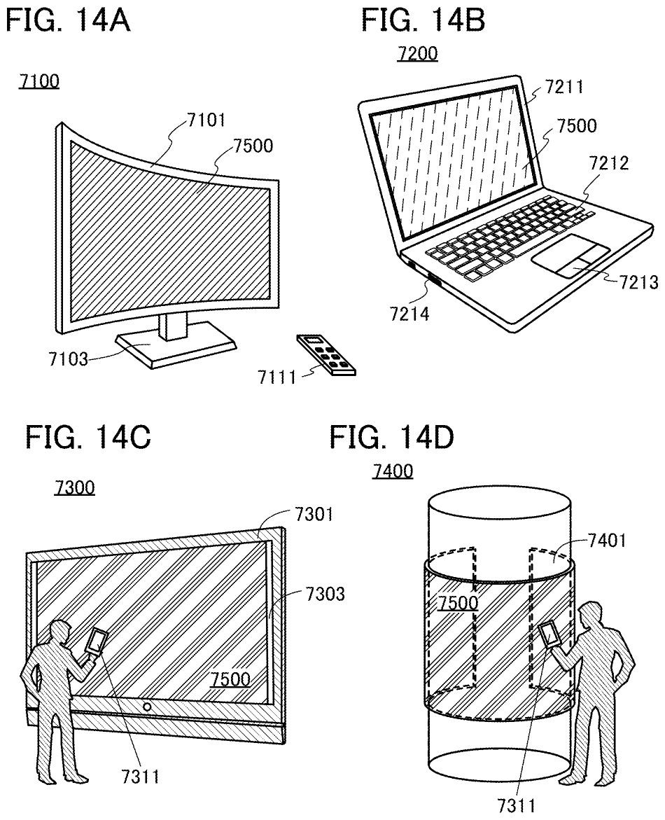

FIG. 14A illustrates an example of a television device. In a television device 7100, a display portion 7500 is incorporated in a housing 7101. Here, a structure in which the housing 7101 is supported by a stand 7103 is illustrated.

Operation of the television device 7100 illustrated in FIG. 14A can be performed with an operation switch provided in the housing 7101 or a separate remote controller 7111. Alternatively, a touch panel may be used for the display portion 7500, and the television device 7100 may be operated by touch on the touch panel. The remote controller 7111 may include a display portion in addition to operation buttons.

Note that the television device 7100 may include a television receiver or a communication device for network connection.

FIG. 14B illustrates a notebook personal computer 7200. The notebook personal computer 7200 includes a housing 7211, a keyboard 7212, a pointing device 7213, an external connection port 7214, and the like. The display portion 7500 is incorporated in the housing 7211.

FIG. 14C and FIG. 14D illustrate examples of digital signage.

Digital signage 7300 illustrated in FIG. 14C includes a housing 7301, the display portion 7500, a speaker 7303, and the like. Furthermore, the digital signage can include an LED lamp, operation keys (including a power switch or an operation switch), a connection terminal, a variety of sensors, a microphone, and the like.

FIG. 14D is digital signage 7400 attached to a cylindrical pillar 7401. The digital signage 7400 includes the display portion 7500 provided along a curved surface of the pillar 7401.

The larger display portion 7500 can increase the amount of information that can be provided at a time and attracts more attention, so that the effectiveness of the advertisement can be increased, for example.

A touch panel is preferably used for the display portion 7500 so that the user can operate the digital signage. Thus, the digital signage can be used not only for advertising but also for providing information that the user needs, such as route information, traffic information, or guidance information on a commercial facility.

As illustrated in FIG. 14C and FIG. 14D, it is preferable that the digital signage 7300 or the digital signage 7400 can work with an information terminal 7311 such as a user's smartphone through wireless communication. For example, information of an advertisement displayed on the display portion 7500 can be displayed on a screen of the portable information terminal 7311. Moreover, by operation of the information terminal 7311, a displayed image on the display portion 7500 can be switched.

It is possible to make the digital signage 7300 or the digital signage 7400 execute a game with use of the information terminal 7311 as an operation means (controller). Thus, an unspecified number of users can join in and enjoy the game concurrently.

The display device of one embodiment of the present invention can be used for the display portion 7500 in FIG. 14A to FIG. 14D. Thus, a high-quality image can be displayed on the display portion 7500.

The electronic devices of this embodiment each include a display portion; however, one embodiment of the present invention can also be used in an electronic device without a display portion.

At least part of this embodiment can be implemented in appropriate combination with the other embodiments described in this specification.

### REFERENCE NUMERALS

10: display device, 11: substrate, 12: substrate, 13: insulating layer, 14: partition, 15B: pixel, 15G: pixel, 15R: pixel, 15: pixel, 21: insulating layer, 25B: coloring layer, 25G: coloring layer, 25R: coloring layer, 29A: resist, 29B: resist mask, 29: lens, 30: light-emitting element, 31A: film, 31: light-emitting layer, 32a: end portion, 32b: end portion, 32: end portion, 33: adhesive layer, 42: conductive layer, 45: light-blocking layer, 52: transistor, 60A: film, 60: conductive layer, 63A: film, 63: insulating layer, 201: driver circuit, 215: display portion, 221: driver circuit, 231: driver circuit, 232: driver circuit, 241: driver circuit, 723: electrode, 726: insulating layer, 728: insulating layer, 729: insulating layer, 741: insulating layer, 742: semiconductor layer, 744a: electrode, 744b: electrode, 746: electrode, 755: impurity, 771: substrate, 772: insulating layer, 810: transistor, 811: transistor, 820: transistor, 821: transistor, 825: transistor, 826: transistor, 842: transistor, 843: transistor, 844: transistor, 845: transistor, 846: transistor, 847: transistor, 4005: sealant, 4011: transistor, 4014: wiring, 4015: electrode, 4017: electrode, 4018: FPC, 4019: anisotropic conductive layer, 4020: capacitor, 4021: electrode, 4041: printed circuit board, 4042: integrated circuit, 4102: insulating layer, 4103: insulating layer, 4110: insulating layer, 4111: insulating layer, 4112: insulating layer, 4200: input device, 4210: touch panel, 4227: electrode, 4228: electrode, 4237: wiring, 4238: wiring, 4239: wiring, 4263: substrate, 4272: FPC, 4273: IC, 6000: display module, 6001: upper cover, 6002: lower cover, 6005: FPC, 6006: display device, 6009: frame, 6010: printed circuit board, 6011: battery, 6015: light-emitting portion, 6016: light-receiving portion, 6017a: light guide portion, 6017b: light guide portion, 6018: light, 6500: electronic device, 6501: housing, 6502: display portion, 6503: power button, 6504: button, 6505: speaker, 6506: microphone, 6507: camera, 6508: light source, 6510: protective member, 6511: display panel, 6512: optical member, 6513: touch sensor panel, 6515: FPC, 6516: IC, 6517: printed circuit board, 6518: battery, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7500: display portion, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: mounting portion, 8202: lens, 8203: main body, 8204: display portion, 8205: cable, 8206: battery, 8300: head-mounted display, 8301: housing, 8302: display portion, 8303: operation button, 8304: fixing unit, 8305: lens, 8306: dial, 8307: dial, 8308: driver portion, 8310: user, 8311: user, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9100: television device, 9101: portable information terminal, 9102: portable information terminal, 9200: portable information terminal, 9201: portable information terminal

1. A display device comprising:
a first conductive layer;
a second conductive layer;
a light-emitting layer;
a lens; and
a first insulating layer,
wherein the light-emitting layer is provided over the first conductive layer,
wherein the second conductive layer is provided over the light-emitting layer,
wherein the lens is provided over the second conductive layer,
wherein the lens comprises a photosensitive material,
wherein an end portion of the lens is located more outward than an end portion of the light-emitting layer and an end portion of the second conductive layer,
wherein the lens comprises an acrylic resin,
wherein the first insulating layer comprises a region in contact with a top surface of the lens, a region in contact with a side surface of the second conductive layer, and a region in contact with a side surface of the light-emitting layer.

2. (canceled)

3. (canceled)

4. The display device according to claim 1, further comprising a second insulating layer,
wherein the second insulating layer is provided between the second conductive layer and the lens, and
wherein an end portion of the second insulating layer is located more inward than the end portion of the lens.

5. A display device comprising:
a first conductive layer;
a second conductive layer;
a third conductive layer;
a fourth conductive layer;
a first light-emitting layer;
a second light-emitting layer;
a first lens;
a second lens;
a first coloring layer;
a second coloring layer; and
a first insulating layer,
wherein the first light-emitting layer is provided over the first conductive layer,
wherein the second conductive layer is provided over the first light-emitting layer,
wherein the first lens is provided over the second conductive layer,
wherein the first coloring layer is provided over the first lens,
wherein the second light-emitting layer is provided over the third conductive layer,
wherein the fourth conductive layer is provided over the second light-emitting layer,
wherein the second lens is provided over the fourth conductive layer,
wherein the second coloring layer is provided over the second lens,
wherein the first lens and the second lens each comprise a photosensitive material,
wherein an end portion of the first lens is located more outward than an end portion of the first light-emitting layer and an end portion of the second conductive layer,
wherein an end portion of the second lens is located more outward than an end portion of the second light-emitting layer and an end portion of the fourth conductive layer,
wherein the first light-emitting layer and the second light-emitting layer are configured to emit light with a same color,
wherein the first coloring layer and the second coloring layer are configured to transmit light with different colors,
wherein the first lens and the second lens each comprises an acrylic resin, and
wherein the first insulating layer comprises a region in contact with a top surface of the first lens, a region in contact with a top surface of the second lens, a region in contact with a side surface of the second conductive layer, a region in contact with a side surface of the fourth conductive layer, a region in contact with a side surface of the first light-emitting layer, and a region in contact with a side surface of the second light-emitting layer.

6. (canceled)

7. (canceled)

8. The display device according to claim 5, further comprising a second insulating layer and a third insulating layer,
wherein the second insulating layer is provided between the second conductive layer and the first lens,
wherein the third insulating layer is provided between the fourth conductive layer and the second lens,
wherein an end portion of the second insulating layer is located more inward than the end portion of the first lens, and
wherein an end portion of the third insulating layer is located more inward than the end portion of the second lens.

9. An electronic device comprising:
the display device according to claim 1; and
an operation button.

10. A method for manufacturing a display device comprising:
forming a first conductive layer over a substrate;
depositing a first film that is to be a light-emitting layer over the first conductive layer;
depositing a second film that is to be a second conductive layer over the first film;
forming a resist mask over the second film to have a region overlapping with the first conductive layer,
etching the second film that and the first film with the use of the resist mask as a mask, so that the second conductive layer and the light-emitting layer are formed, and
heating the substrate to turn the resist mask into a lens.

11. A method for manufacturing a display device according to claim 10,
wherein a first insulating layer is deposited after the formation of the lens, and
wherein the first insulating layer is deposited by an ALD method.

12. (canceled)

13. The method for manufacturing a display device according to claim 10,
wherein a third film that is to be a second insulating layer is deposited after the deposition of the second film and before the formation of the resist mask, and
wherein the third film, the second film, and the first film are etched with the use of the resist mask as a mask after the formation of the resist mask, so that the second insulating layer, the second conductive layer, and the light-emitting layer are formed.

14. An electronic device comprising:
the display device according to claim 5; and
an operation button.

15. The display device according to claim 1, further comprising:
a first transistor electrically connected to the first conductive layer; and
a first capacitor,
wherein the lens overlaps with the first transistor and the first capacitor.

16. The display device according to claim 5, further comprising:
a first transistor electrically connected to the first conductive layer; and
a first capacitor,
wherein the first lens overlaps with the first transistor and the first capacitor.

17. The display device according to claim 1, further comprising:
a first transistor electrically connected to the first conductive layer; and
a first capacitor,
wherein the lens overlaps with the first transistor and the first capacitor, and
wherein the first conductive layer, the light-emitting layer, and the second conductive layer overlap with the first transistor and the first capacitor.

18. The display device according to claim 5, further comprising:
a first transistor electrically connected to the first conductive layer; and
a first capacitor,
wherein the first lens overlaps with the first transistor and the first capacitor, and
wherein the first conductive layer, the first light-emitting layer, and the second conductive layer overlap with the first transistor and the first capacitor.

19. The display device according to claim 1, further comprising:
an adhesive layer; and
a coloring layer,
wherein the adhesive layer is provided between the first insulating layer and the coloring layer, and
wherein the adhesive layer is in contact with a top surface of the first insulating layer.

20. The display device according to claim 5, further comprising:
an adhesive layer,
wherein the adhesive layer is provided between the first insulating layer and the first coloring layer, and
wherein the adhesive layer is in contact with a top surface of the first insulating layer.

21. The display device according to claim 1, wherein, in a cross-sectional view, the first insulating layer is not in contact with a top surface of the second conductive layer and a top surface of the light-emitting layer.

22. The display device according to claim 5, wherein, in a cross-sectional view, the first insulating layer is not in contact with a top surface of the second conductive layer and a top surface of the first light-emitting layer.
